(19) United States
(12) Patent Application Publication
(10) Pub. No.: US 2026/0051072 A1
(43) Pub. Date: Feb. 19, 2026

(54) IMAGE MEASUREMENT APPARATUS AND SETTING SUPPORT DEVICE FOR IMAGE MEASUREMENT APPARATUS

(71) Applicant: Keyence Corporation, Osaka (JP)

(72) Inventors: Sho MIKAWA, Osaka (JP); Haoyang YU, Osaka (JP)

(73) Assignee: Keyence Corporation, Osaka (JP)

(21) Appl. No.: 19/368,325

(22) Filed: Oct. 24, 2025

Related U.S. Application Data
(63) Continuation of application No. PCT/JP2025/013957, filed on Apr. 7, 2025.

(30) Foreign Application Priority Data
Apr. 15, 2024 (JP) 2024-065401
Mar. 25, 2025 (JP) 2025-049973

(51) Int. Cl. G06T 7/543; G06F 30/17; G06T 7/60; G06T 7/73; G06T 11/20

(52) U.S. Cl. CPC G06T 7/543; G06F 30/17; G06T 7/60; G06T 7/75; G06T 11/203; G06T 2200/24; G06T 2207/30164

(57) ABSTRACT

An image measurement apparatus includes an epi-illumination section and a transmitted illumination section, a drawing reception section that receives drawing data, a matching section that matches a workpiece shape included in the drawing data received by the drawing reception section with a workpiece representation included in an image generated by the imaging section, a measurement setting section that receives an instruction of a measurement position or a measurement item in the workpiece shape and reflects the measurement position or the measurement item as a measurement position or a measurement item for the workpiece representation after the workpiece shape included in the drawing data and the workpiece representation included in the image are matched by the matching section, and an automatic adjustment section that automatically adjusts, for every measurement element, a measurement condition for extracting each measurement element corresponding to each measurement position or measurement item.

### CROSS-REFERENCE TO RELATED APPLICATIONS

The present application is a continuation of International Patent Application No. PCT/JP2025/013957, filed Apr. 7, 2025, which claims foreign priority based on Japanese Patent Application No. 2024-065401, filed Apr. 15, 2024, and No. 2025-049973, filed Mar. 25, 2025, the contents of which are incorporated herein by references.

### TECHNICAL FIELD

The present disclosure relates to an image measurement apparatus and a setting support device for the image measurement apparatus.

### BACKGROUND ART

An image measurement apparatus executes dimension measurement of each part by using an image generated by capturing a workpiece by an imaging section. For example, an image measurement apparatus of Patent Literature 1 includes an adjustment section that adjusts a focus of an imaging section, and can obtain a height of a workpiece with a translucent plate as a reference based on a control parameter of the adjustment section when the workpiece is in focus and a control parameter of the adjustment section when the translucent plate on which the workpiece is mounted is in focus. In addition, an image measurement apparatus of Patent Literature 2 can acquire a luminance distribution of a workpiece image newly generated by an imaging section at the time of operation, and determine a measurement point on the newly generated workpiece image on the basis of a position of the measurement point and luminance information stored in advance in a storage section.

### CITATION LIST

### Patent Literature

Patent Literature 1: JP 7252019 B
Patent Literature 2: JP 7280810 B

### SUMMARY OF INVENTION

### Technical Problem

Incidentally, in a case where the image measurement apparatus is used, it is necessary to set an inspection measurement item. In general, a user understands the inspection measurement items instructed by the drawings, adjusts observation conditions of the image measurement apparatus, and instructs the image measurement apparatus to associate a captured image with a measurement element. As a result, the user creates a measurement program. In addition, in order to assist the creation of the measurement program, some image measurement apparatuses may take in drawing data such as DXF data as inspection data and automatically set the inspection measurement item. However, the measurement item and the measurement element are collectively generated on the basis of a predetermined rule, and there is a problem that the measurement program intended by the user is not obtained by generating unnecessary measurement items and measurement elements.

The present disclosure has been made in view of such a point, and an object thereof is to easily create a measurement program intended by a user.

### Solution to Problem

In order to achieve the above object, an image measurement apparatus according to an aspect of the present disclosure includes a mounting table that includes a translucent plate having translucency and on which a workpiece is mounted on a first surface of the translucent plate, a transmitted illumination section that is provided below the translucent plate and irradiates the workpiece mounted on the translucent plate with transmitted illumination light, an epi-illumination section that is provided above the translucent plate and irradiates the workpiece mounted on the translucent plate with epi-illumination light, an imaging section that is provided above the mounting table and captures the workpiece mounted on the mounting table to generate an image including a workpiece representation, a drawing reception section that receives drawing data including a workpiece shape and dimensional information, a matching section that matches the workpiece shape included in the drawing data received by the drawing reception section with the workpiece representation included in the image generated by the imaging section, a specifying section that specifies a correspondence relationship between a measurement element in the workpiece shape and the dimensional information, a display screen generation section that generates a display screen that displays, based on reception of a selection operation of a figure corresponding to the measurement element in the workpiece shape or the dimensional information and the correspondence relationship specified by the specifying section, figures corresponding to candidates for the measurement element corresponding to the reception and dimensional information on the drawing data, a measurement setting section that reflects an element type, an element position, and a measurement item corresponding to a measurement element selected from the candidates in measurement setting, and a measurement control section that controls measurement on the workpiece representation based on an image including a workpiece representation generated by capturing the workpiece by the imaging section upon reception of a measurement instruction, and the element type, the element position, and the measurement item reflected in the measurement settings by the measurement setting section

According to this configuration, when the drawing data including the workpiece shape is received, the workpiece representation included in the image generated by the imaging section and the workpiece shape included in the drawing data are automatically matched. In addition, when the selection operation of the figure corresponding to the measurement element in the workpiece shape or the dimensional information is received, the figures corresponding to the candidates for the measurement element corresponding to the reception and the dimensional information are displayed on the drawing data. Further, measurement is executed on the workpiece representation on the basis of the image including the workpiece representation and the element type, the element position, and the measurement item reflected in the measurement setting. Accordingly, the user can perform desired measurement on the workpiece without performing an associating work, a positioning work between the workpiece image and the drawing data, or the like.

In addition, as another aspect, a setting support device for an image measurement apparatus that supports setting of the image measurement apparatus can be assumed. The setting support device for an image measurement apparatus includes a drawing reception section that receives drawing data including a workpiece shape and dimensional information, a matching section that matches the workpiece shape included in the drawing data received by the drawing reception section with the workpiece representation included in the image generated by the imaging section, a specifying section that specifies a correspondence relationship between a measurement element in the workpiece shape and the dimensional information, a display screen generation section that generates a display screen that displays, based on reception of a selection operation of a figure corresponding to the measurement element in the workpiece shape or the dimensional information and the correspondence relationship specified by the specifying section, figures corresponding to candidates for a measurement element corresponding to the reception and dimensional information on the drawing data, and a measurement setting section that reflects an element type, an element position, and a measurement item corresponding to a measurement element selected from the candidates in measurement setting, in which setting processing is executed such that the measurement control section controls measurement of the workpiece based on an image including a workpiece representation generated by capturing the workpiece by the imaging section upon reception of a measurement instruction, the element type, the element position, and the measurement item reflected in the measurement setting by the measurement setting section.

### Advantageous Effects of Invention

As described above, it is possible to automatically match the workpiece shape and the workpiece representation included in the drawing data and automatically reflect the measurement position or the measurement item for the workpiece representation, and further, it is possible to automatically adjust the measurement condition for every measurement element. As a result, it is possible to easily perform desired measurement even though the user does not have specialized knowledge of CAD or a measuring instrument.

### BRIEF DESCRIPTION OF DRAWINGS

FIG. 1 is a diagram illustrating a schematic configuration of an image measurement apparatus according to the present embodiment.

FIG. 2 is a front view of an apparatus body.

FIG. 3 is a perspective view of the apparatus body.

FIG. 4 is a block diagram of the image measurement apparatus.

FIG. 5A is a diagram for explaining an outline of an automation function of the image measurement apparatus.

FIG. 5B is a diagram illustrating an example of CAD data.

FIG. 6A is a flowchart illustrating an example of processing executed by the image measurement apparatus.

FIG. 6B is a diagram illustrating a type of a drawing to be taken in and a relationship between pixels in each part.

FIG. 7 is a diagram illustrating an example of a user interface screen for drawing display.

FIG. 8 is a flowchart illustrating an example of scaling estimation processing.

FIG. 9 is a diagram illustrating an example of taken drawing data.

FIG. 10 is a diagram illustrating an example of a user interface screen displaying drawing guide.

FIG. 11 is a flowchart illustrating contour best fit processing example.

FIG. 12 is a diagram illustrating an example of a workpiece image and an edge image.

FIG. 13 is a diagram illustrating an example in which a template image is generated from an edge image.

FIG. 14 is a diagram illustrating an example of a user interface screen for positioning confirmation.

FIG. 15 is a diagram illustrating an example of a user interface screen of two-screen display.

FIG. 16 is a flowchart illustrating processing of a first example of programming assistance.

FIG. 17A is a diagram corresponding to FIG. 15 in a case where a dimension is clicked.

FIG. 17B is a diagram corresponding to FIG. 17A in a case where a corresponding measurement item is displayed.

FIG. 17C is a diagram corresponding to FIG. 17A in a case where display corresponding to candidates for a measurement element is performed.

FIG. 17D is a diagram corresponding to FIG. 17C after a confirmation operation.

FIG. 18 is a diagram corresponding to FIG. 15 displayed in a case where the candidates for the measurement element are presented.

FIG. 19 is a flowchart illustrating processing of a second example of the programming assistance.

FIG. 20 is a diagram illustrating a window displayed at the time of edge extraction condition setting.

FIG. 21 is a diagram for explaining edge extraction processing.

FIG. 22 is a flowchart illustrating an outline of automatic adjustment by an automatic adjustment section.

FIG. 23 is a diagram illustrating an example of a user interface screen of measurement setting.

FIG. 24 is a diagram corresponding to FIG. 23 illustrating a measurement element automatically adjusted.

FIG. 25 is a diagram illustrating an example of a user interface screen of detail display.

FIG. 26 is an automatic adjustment flowchart.

FIG. 27 is a flowchart illustrating an example of an adjustment order of a plurality of measurement conditions.

FIG. 28A is a timing chart illustrating a concept of background automatic adjustment.

FIG. 28B is a timing chart illustrating another example of the background automatic adjustment.

FIG. 29 is a flowchart at the time of operation of the image measurement apparatus.

FIG. 30 is a block diagram of a setting support device for the image measurement apparatus.

FIG. 31 is a flowchart illustrating an example of offline programming processing.

FIG. 32 is a diagram illustrating an example of a user interface screen displaying an image on the basis of the taken drawing data.

FIG. 33 is a diagram corresponding to FIG. 32 illustrating a state where designation of an intake range is accepted.

FIG. 34 is a diagram corresponding to FIG. 32 illustrating a state where drawing data of the intake range is displayed.

FIG. 35 is a diagram corresponding to FIG. 34 illustrating a state where flood filling processing is executed.

FIG. 36 is a diagram illustrating a setting window for flood filling processing.

FIG. 37 is a diagram illustrating an example of a user interface screen capable of performing two-screen display.

FIG. 38 is a diagram corresponding to FIG. 37 in a state where a dimension is selected.

FIG. 39 is a diagram illustrating an example of a pattern registration user interface screen.

FIG. 40 is a diagram corresponding to FIG. 37 in a case where there is no filling.

FIG. 41 is a diagram corresponding to FIG. 38 in a case where there is no filling.

FIG. 42 is a flowchart illustrating an example of processing in a case where a program created offline is read online into the image measurement apparatus.

FIG. 43 is a diagram illustrating an example of a user interface screen displayed in a case where a pattern image is registered.

FIG. 44 is a diagram illustrating a screen on which the created program is superimposed on a workpiece W mounted on a stage.

FIG. 45 is a diagram corresponding to FIG. 4 illustrating an example of a configuration including a specifying section.

### DESCRIPTION OF EMBODIMENTS

Hereinafter, embodiments of the present invention will be described in detail with reference to the drawings. Note that, the following description of preferred embodiments is merely exemplary in nature and is not intended to limit the present invention, the application thereof, or the use thereof.

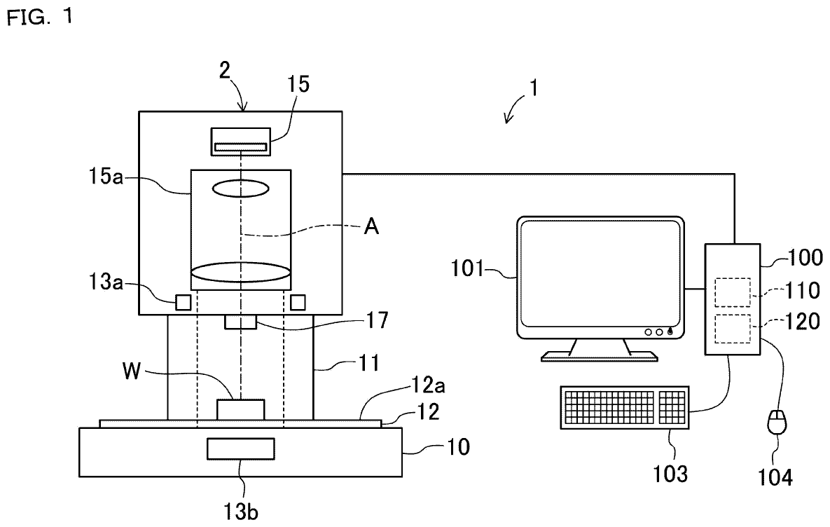

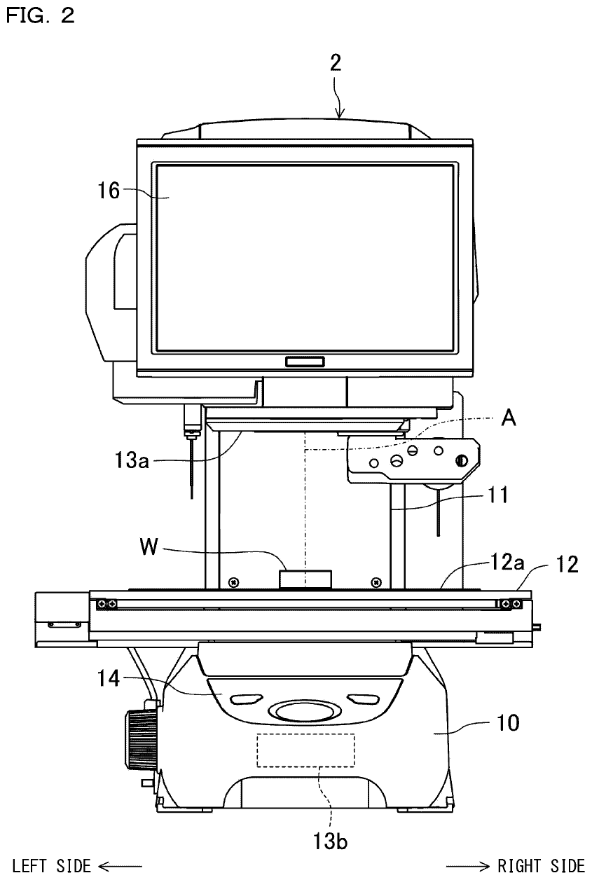

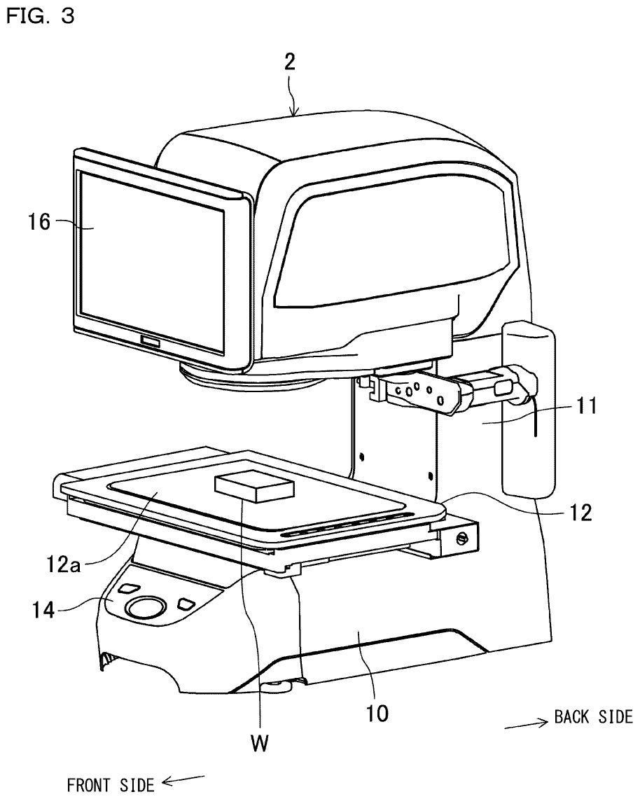

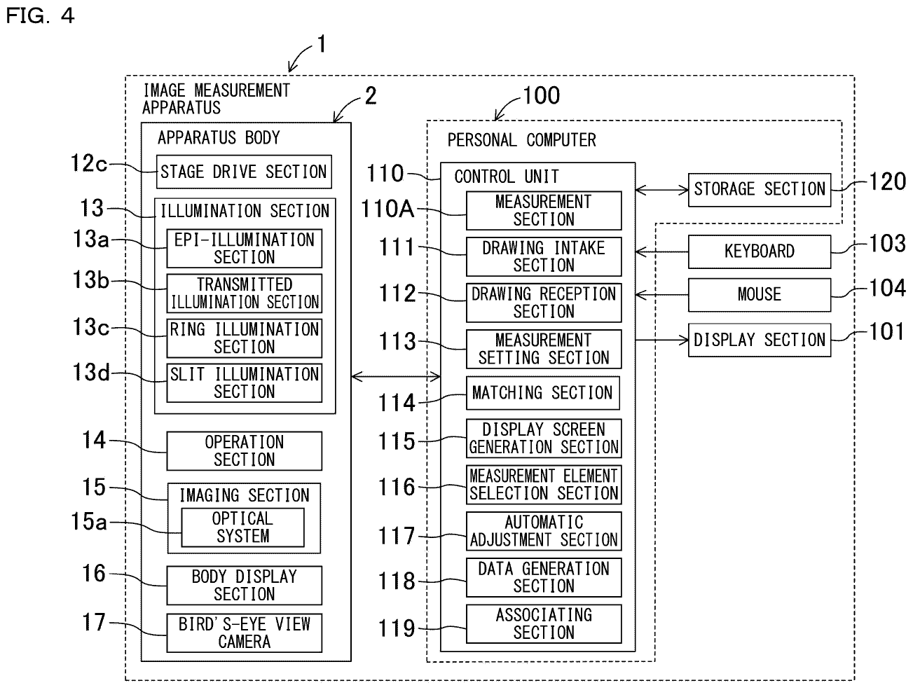

FIG. 1 is a diagram illustrating a schematic configuration of an image measurement apparatus 1 according to an embodiment of the present invention. FIG. 2 is a front view of the image measurement apparatus 1 according to the embodiment of the present invention, and FIG. 3 is a perspective view of the image measurement apparatus 1 according to the embodiment of the present invention. In addition, FIG. 4 is a block diagram schematically illustrating a configuration of the image measurement apparatus 1. The image measurement apparatus 1 measures, for example, dimensions and the like of various workpieces W (illustrated in FIG. 2) as measurement objects, and can also be referred to as a dimension measurement apparatus, a dimension measurement system, or the like.

As illustrated in FIG. 1, the image measurement apparatus 1 includes an apparatus body 2, a personal computer 100, a display section 102, a keyboard 103, and a mouse 104. The personal computer 100 may be a desktop type or a notebook type. A general-purpose personal computer in which a computer program (software) for executing control and processing to be described later is installed can be used as the personal computer 100.

The personal computer 100 includes a control unit 110 and a storage section 120. The control unit 110 includes a central processing unit included in the personal computer 100, a ROM, a RAM, and the like. The storage section 120 is connected to the control unit 110. The storage section 120 includes, for example, a solid state drive (SSD), a hard disk drive, or the like. The control unit 110 is connected to each piece of hardware, and a unit that controls an operation of each piece of hardware and executes a software function according to a computer program stored in the storage section 120. The control unit 110 executes the software function, and thus, a measurement section 110A, a drawing intake section 111, a drawing reception section 112, a measurement setting section 113, a matching section 114, a display screen generation section 115, a measurement element selection section 116, an automatic adjustment section 117, a data generation section 118, an associating section 119, and the like can be configured. The measurement section 110A, the drawing intake section 111, the drawing reception section 112, the measurement setting section 113, the matching section 114, the display screen generation section 115, the measurement element selection section 116, the automatic adjustment section 117, the data generation section 118, and the associating section 119 may be configured by a combination of the software function and hardware. In addition, a part of the measurement section 110A, the drawing intake section 111, the drawing reception section 112, the measurement setting section 113, the matching section 114, the display screen generation section 115, the measurement element selection section 116, the automatic adjustment section 117, the data generation section 118, and the associating section 119 may be configured by an arithmetic processing device different from the control unit 110. In the RAM of the control unit 110, a load module is expanded when the computer program is executed, and temporary data and the like generated at the time of execution of the computer program are stored. Note that, an arithmetic processing device dedicated to image measurement may be provided instead of the personal computer 100.

The display section 102 includes, for example, a liquid crystal display, an organic EL display, or the like, and is connected to the control unit 110. The control unit 110 controls the display section 102 to display various user interface screens on the display section 102.

The keyboard 103 and the mouse 104 are typical examples of members for operating the control unit 110. When the keyboard 103 and the mouse 104 are operated by the user, the control unit 110 detects operation states of the keyboard 103 and the mouse 104, and controls each part in accordance with the operation states of the keyboard 103 and the mouse 104. The member for operating the control unit 110 may be a touch panel capable of detecting a touch operation of the user, various pointing devices, or the like.

In this embodiment, an example in which the control unit 110 is separated from the apparatus body 2 and is connected to be able to communicate by a communication line or the like will be described, but the configuration of the image measurement apparatus 1 is not limited to the above-described configuration, and the control unit 110 may be incorporated and integrated in the apparatus body 2. Similarly, the storage section 120 may be separated from the apparatus body 2, or may be incorporated and integrated in the apparatus body 2. The control unit 110 and the storage section 120 may be separate bodies or may be integrated. A part or all of the storage section 120 may be a cloud storage.

Note that, in the description of the present embodiment, regarding the apparatus body 2 of the image measurement apparatus 1, a side positioned on the front when facing the user positioned in an assumed access direction is referred to as a front side, and a side positioned on the back is referred to as a back side. In addition, when the apparatus body 2 of the image measurement apparatus 1 is viewed from the user, a side positioned on the left is referred to as a left side, and a side positioned on the right is referred to as a right side. When the definition is made uniform as viewed from the user, the front side can be referred to as a near side, and the back side can be referred to as a far side. This is only defined for the sake of convenience in description, and does not limit a direction at the time of actual use.

As illustrated in FIGS. 1 to 3, the apparatus body 2 includes a base 10 and an arm 11 extending upward from the back side of the base 10. A stage 12 serving as a mounting table for mounting the workpiece W is provided above the base 10. The stage 12 extends substantially horizontally. A translucent plate 12a having translucency for transmitting light is provided in the vicinity of a central portion of the stage 12. For example, an upper surface of the translucent plate 12a is a first surface, and the workpiece W is mounted on the first surface of the translucent plate 12a. In the following description, the first surface of the translucent plate 12a is referred to as an upper surface of the translucent plate 12a. The stage 12 including the translucent plate 12a can be driven in a horizontal direction and a vertical direction by a stage drive section 12c illustrated in FIG. 4. A driving direction of the stage 12 by the stage drive section 12c is a left-right direction (X direction), a depth direction (Y direction), and a height direction (Z direction). The stage drive section 12c having received an instruction from the control unit 110 drives the stage 12 by an instructed movement amount in an instructed direction within a predetermined driving range. The stage 21 can be moved by an electric actuator or the like, but may be manually moved by the user.

As illustrated in FIG. 4, the apparatus body 2 includes an illumination section 13. The illumination section 13 includes an epi-illumination section 13a built in an upper portion of the arm 11 and a transmitted illumination section 13b built in the base 10. As indicated by a broken line in FIG. 2, the transmitted illumination section 13b is provided below the translucent plate 12a, and an orientation thereof is set so as to emit light upward. The light emitted from the transmitted illumination section 13b is transmitted through the translucent plate 12a upward, and is emitted from below to the workpiece W mounted on the upper surface of the translucent plate 12a. That is, the transmitted illumination section 13b is a member that irradiates the workpiece W mounted on the translucent plate 12a with transmitted illumination light. The transmitted illumination section 13b includes a light source for illumination, an illumination diaphragm, and an illumination lens. The transmitted illumination section 13b may be an object-side telecentric system that shapes light from the light source with an aperture diaphragm and renders parallel light with a lens. The illumination diaphragm may be a variable diaphragm. In this case, for example, it is possible to switch between a mode in which the light with which the workpiece W is irradiated is parallel light by setting a shape of the diaphragm to a shape corresponding to an entrance pupil of the object-side telecentric system and a mode in which the light with which the workpiece W is irradiated is light rays at various angles by setting the shape of the diaphragm to an open shape.

The epi-illumination section 13a is provided above the translucent plate 12a, and an orientation thereof is set so as to emit light downward. The light emitted from the epi-illumination section 13a is emitted to the workpiece W mounted on the translucent plate 12a from above. That is, the epi-illumination section 13a is a member that irradiates the workpiece W mounted on the translucent plate 12a with epi-illumination light.

The illumination section 13 may include, for example, a ring illumination section 13c formed in a ring shape surrounding an optical axis A of an imaging section 15 to be described later, a slit illumination section 13d that illuminates the workpiece W from the side, and the like.

An operation section 14 is provided on the front side of the base 10. The operation section 14 includes various buttons, switches, dials, and the like operated by the user. Examples of the button included in the operation section 14 include a measurement start button. The control unit 110 can also detect an operation state of the operation section 14 and control each part in accordance with the operation state of the operation section 14. The operation section 14 may include a touch panel or the like capable of detecting a touch panel operation of the user. In this case, the operation section 14 can be incorporated in a body display section 16 to be described later.

The epi-illumination section 13a and the transmitted illumination section 13b are controlled by the control unit 110. For example, when the control unit 110 detects that a measurement start operation of the workpiece W is performed by the operation section 14, the epi-illumination section 13a or the transmitted illumination section 13b can be turned on to emit the epi-illumination light or the transmitted illumination light.

As illustrated in FIG. 1, the imaging section 15 is provided in the arm 11 so as to be positioned above the stage 12. The imaging section 15 is a section that captures the workpiece W mounted on the stage 12 and generates an image including a workpiece representation. In the following description, the image including the workpiece representation is referred to as a workpiece image.

As a typical example of the imaging section 15, for example, a camera having an imaging element such as a charge coupled device (CCD) or a complementary metal oxide semiconductor (CMOS) can be exemplified. As illustrated in FIG. 1, the optical axis A of the imaging section 15 is set vertically downward, and an optical system 15a including a light receiving lens and an imaging lens is provided coaxially with the optical axis A of the imaging section 15. For example, the optical system 15a includes an object-side telecentric lens. As a result, even in a case where a focal depth is increased, a representation of the workpiece W having the same size can be captured regardless of a distance to the workpiece W. When the focal depth is shallow and a focal position is determined, the lens is not necessarily a telecentric lens. The optical system 15a is configured to be able to change a magnification. For example, a plurality of lenses having different magnifications are arranged at different optical path positions, and the magnification is changed by switching an optical path to be adopted. In addition, the optical system 15a may include a zoom lens. In addition, a diaphragm that adjusts the amount of light incident on the imaging section 15 is also provided in the optical system 15a.

The imaging section 15 may be an imaging unit including the optical system 15a or an imaging element not including the optical system 15a. Light emitted from the epi-illumination section 13a and reflected by the workpiece W, light emitted from the transmitted illumination section 13b and transmitted through the translucent plate 12a of the stage 12, and the like are incident on the imaging section 15. As a method of focus adjustment by the optical system 15a, for example, a method for performing adjustment on the basis of a position where sharpness, contrast, maximum luminance, and the like of the workpiece image become maximum, a method for arranging a distance measuring sensor and performing adjustment on the basis of a measurement signal of the distance measuring sensor, and the like can be applied.

The imaging section 15 generates the workpiece image on the basis of the amount of received light. The imaging section 15 is connected to the control unit 110, and the workpiece image generated by the imaging section 15 is transmitted, as image data, to the control unit 110. In addition, the control unit 110 can control the imaging section 15. For example, when the control unit 110 detects that the measurement start operation of the workpiece W is performed by the operation section 14, the imaging section 15 is caused to execute imaging processing in a state where the epi-illumination section 13a or the transmitted illumination section 13b is turned on to emit light. As a result, the imaging section 15 generates the workpiece image, and the generated workpiece image is transmitted to the control unit 110.

In the control unit 110, the workpiece image transmitted from the imaging section 15 can be incorporated into the user interface screen and displayed on the display section 101 or the body display section 16. The body display section 16 is provided on the upper portion of the arm 11 so as to face the front. The body display section 16 includes, for example, a liquid crystal display, an organic EL display, or the like. The control unit 110 can also display various user interface screens on the body display section 16 by controlling the body display section 16.

The measurement section 110A is provided in the control unit 110. The measurement section 110A extracts an edge (contour) of the workpiece W to generate an edge image by executing image processing such as edge extraction processing on the workpiece image transmitted from the imaging section 15. The measurement section 110A measures a dimension of each part of the workpiece W by using the generated edge image. Measurement parts of the dimensions can be designated in advance by the user as will be described later. The measurement section 110A calculates a dimension corresponding to the measurement part specified by the user.

The apparatus body 2 also includes, but not necessarily, a bird's-eye view camera 17. The bird's-eye view camera 17 is provided above the translucent plate 12a, and is a camera for capturing the workpiece W mounted on the translucent plate 12a at an angle viewed from above to generate a bird's-eye view image. The bird's-eye view camera 17 includes an imaging element similar to the imaging section 15. The bird's-eye view image generated by the bird's-eye view camera 17 is transmitted to the control unit 110. A position of the bird's-eye view camera 17 is not particularly limited, but for example, in a case where the bird's-eye view camera is positioned on the front side of the imaging section 15, the bird's-eye view camera can also be referred to as a front camera, for example.

### (Measurement Setting)

Here, in a case where the image measurement apparatus of the related art is used, it is necessary to set inspection measurement items. In general, the user understands the inspection measurement items instructed by the drawings, adjusts observation conditions of the image measurement apparatus, and instructs the image measurement apparatus to associate a captured image with a measurement element. Then, the user instructs the image measurement apparatus to adjust the measurement condition. As described above, the user needs to perform a procedure of understanding the drawing instruction, adjusting the observation conditions, associating an imaging screen with the measurement element, and adjusting the measurement conditions for all the elements to be measured. In addition, in order to assist the setting of the inspection measurement items, the user may take in, as inspection data, drawing data such as DXF data into the image measurement apparatus and set the inspection measurement items. However, it is necessary to position the workpiece image and the drawing data, and the user needs to create a reference element (for example, a reference coordinate system or the like) in order to position the workpiece image and the drawing data. Further, it is necessary to designate a measurement position, a measurement element, and the like for the drawing data taken into the image measurement apparatus, and it is also necessary to adjust measurement conditions such as focus adjustment for the imaging section and illumination adjustment for the illumination section. For this reason, in the image measurement apparatus of the related art, the user needs to have specialized knowledge of a computer aided design (CAD) or a measuring instrument, and there is a problem that a person who can handle the image measurement apparatus is limited.

In contrast, the image measurement apparatus 1 of the present embodiment has an automation function capable of almost automatically performing the positioning, the designation of the measurement element, the adjustment of the imaging section, the adjustment of the illumination section, and the like. The automation function is provided, and thus, it is possible to easily perform desired measurement even though the user does not have specialized knowledge of CAD or a measuring instrument. Note that, the above-described DXF is a Drawing Exchange Format, and is a format in which two-dimensional and three-dimensional shapes are expressed in a vector format.

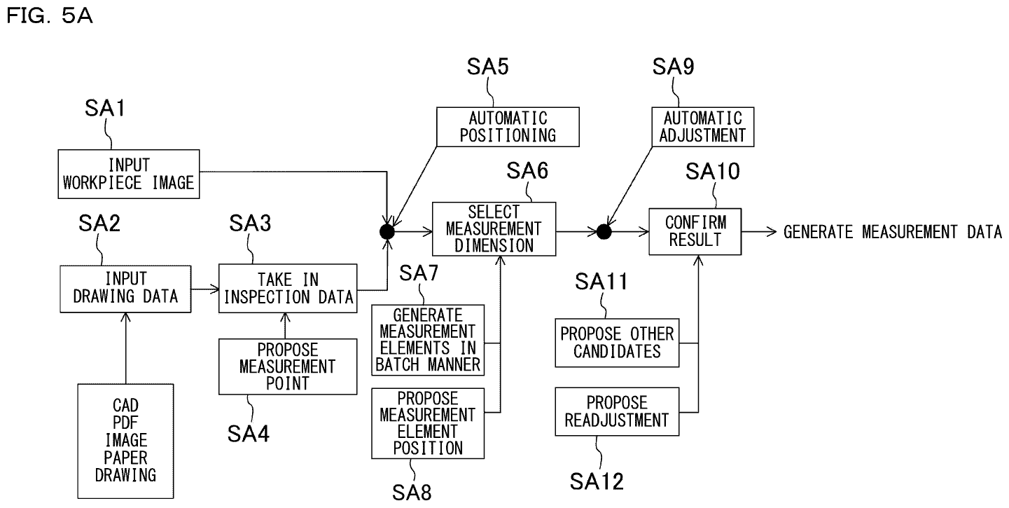

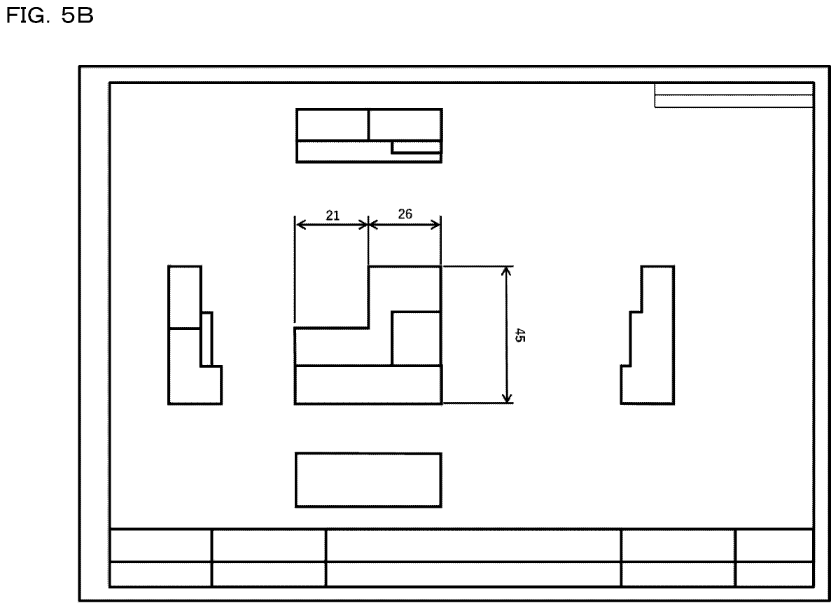

FIG. 5A illustrates an outline of the automation function of the image measurement apparatus 1. The user inputs the workpiece image generated by the imaging section 15 and the drawing data in steps SA1 and SA2 to the image measurement apparatus 1. In step SA2, any of CAD data, PDF data, image data, and paper drawings can be input. FIG. 5B illustrates an example of CAD data.

In step SA3, the image measurement apparatus 1 takes in the inspection data from the drawing data. The drawing data sometimes includes one projection view such as a front view or a plan view for inspection, but often includes a plurality of projection views such as a three-view drawing or a six-view drawing. The image measurement apparatus 1 may partially take in, as the inspection data, a region to be taken in designated by the user from the plurality of projection views included in the drawing data in step SA3. At this time, a region including a projection view having a large information amount of information regarding measurement may be automatically determined from the drawing data, and the determined measurement point may be proposed to the user (step SA4).

In step SA5, the image measurement apparatus 1 executes positioning of the workpiece image input in step SA1 with the drawing data input in step SA2. When measurement dimension selection is performed in step SA6, measurement elements are generated in a batch manner on the basis of information regarding an outline extracted from the drawing data in step SA7 or a measurement element position is proposed on the basis of information regarding an outline extracted from the drawing data in step SA8, and an instruction from the user for the proposed measurement element position is sequentially received to generate the measurement element. In step SA9, the measurement condition is automatically adjusted for every measurement element, and in step SA10, the user can confirm the measurement result. At this time, in step SA11, the image measurement apparatus 1 proposes another candidate for the measurement condition, and in step SA12, the image measurement apparatus 1 proposes readjustment of the measurement condition. As described above, the image measurement apparatus 1 generates measurement data. Only a part of a plurality of kinds of processing illustrated in FIG. 5A may be executable.

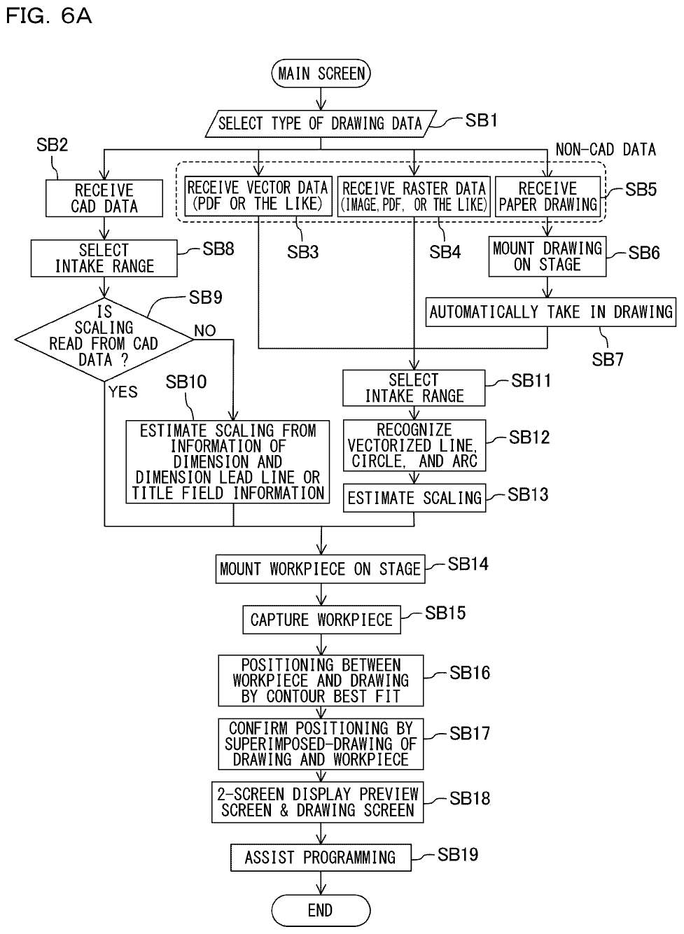

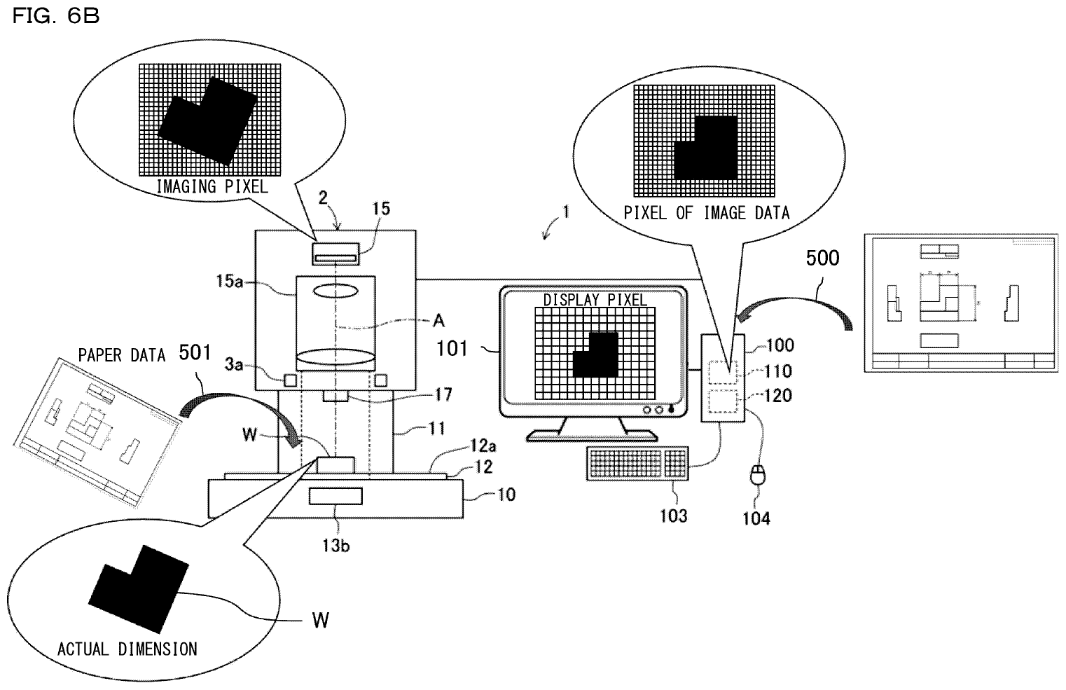

Hereinafter, a detailed description will be given with reference to the flowchart illustrated in FIG. 6A. In the flowchart illustrated in FIG. 6A, first, the display screen generation section 115 of the control unit 110 generates a main screen (not illustrated) and displays the main screen on the display section 101 and the body display section 16. Note that, the main screen may be displayed only on one of the display section 101 and the body display section 16. Hereinafter, the same applies to the screen display, and the main screen may be displayed on both the display section 101 and the body display section 16, or may be displayed on only one thereof.

Step SB1 is a type selection step of the drawing data. The drawing data is drawing data including a workpiece shape, and may be CAD data illustrated in FIG. 5B or non-CAD data. The non-CAD data is data such as a PDF or an image in which a design value (dimension) and a lead line (line used for dimensioning) are not associated with each other among pieces of data including information necessary for creating a measurement program, such as a design value and a tolerance of a workpiece which is a measurement object. However, since a format such as raster or vector is not limited, the non-CAD data includes, for example, image data and PDF data as raster data, and PDF data as data in which raster data and vector data are mixed, in addition to PDF data as vector data. Here, the image data includes data obtained by scanning a paper drawing (paper data illustrated in FIG. 6B) in addition to JPEG data, PNG data, and TIFF data. Here, the CAD data generally refers to design drawing data, but is not limited thereto. The CAD data may be inspection drawing data as long as the CAD data is drawing data in which dimensions such as an inspection value and a line used for dimensioning such as a dimension line are associated with each other.

In step SB1, for example, the user can select a type of the drawing data by operating a type selection button or the like of the drawing data displayed on the main screen. That is, the control unit 110 includes a drawing intake section 111 for taking in a drawing to be taken and a drawing reception section 112 for receiving a drawing. The drawing intake section 111 is a portion that selectively takes in drawing data including a workpiece shape in accordance with an intake instruction from the user. In addition, the drawing reception section 112 receives drawing data including a workpiece shape taken in by the drawing intake section 111.

Specifically, the drawing intake section 111 receives selection of “electronic file” or “paper drawing” as the type of the drawing data to be taken in as described above. After the selection of the type of the drawing data in step SB1 is received, in a case where the type of the drawing data is “electronic file”, the drawing intake section 111 takes in the electronic file as indicated by an arrow 500 in FIG. 6B. In a case where the taken electronic file is CAD data, the processing proceeds to step SB2. The CAD data taken in by the drawing intake section 111 is received by the drawing reception section 112.

In addition, after the selection of the type of the drawing data in step SB1 is received, in a case where the type of the drawing data is “electronic file”, the drawing intake section 111 takes in the electronic file. In a case where the taken electronic file is vector data, the processing proceeds to step SB3. The vector data taken in by the drawing intake section 111 is received by the drawing reception section 112.

In addition, after the selection of the type of the drawing data in step SB1 is received, in a case where the type of the drawing data is “electronic file”, the drawing intake section 111 takes in the electronic file. In a case where the taken electronic file is raster data, the processing proceeds to step SB4. The vector data taken in by the drawing intake section 111 is received by the drawing reception section 112. In a case where the type of the drawing data is CAD data, vector data, or raster data, the drawing reception section 112 can receive the data by the user performing an operation to designate the data from a saving place of the data.

On the other hand, after the selection of the type of the drawing data in step SB1 is received, in a case where the type of the drawing data is “paper drawing”, the drawing intake section 111 advances the processing to step SB5. When the drawing data of the paper drawing is taken in, the processing proceeds to step SB6, and the user mounts the paper drawing on an upper surface of the stage 12 as indicated by an arrow 501 in FIG. 6B. Thereafter, the processing proceeds to step SB7, and the image measurement apparatus 1 executes automatic intake processing of the drawing. Specifically, when the user gives an intake instruction after the paper drawing is mounted on the upper surface of the stage 12, the control unit 110 captures the paper drawing by the imaging section 15 and takes in the image as the drawing data by the drawing intake section 111. As described above, in the case of the paper drawing, the drawing intake section 111 can take in the image obtained by capturing the paper drawing as the drawing data. When the drawing data of the paper drawing is taken in, the drawing reception section 112 receives the drawing data of the paper drawing.

At the time of capturing the paper drawing, in a case where the paper drawing is larger than a visual field range of the imaging section 15, the control unit 110 gives an instruction to the stage drive section 12c to move the stage 12 in the horizontal direction, and then another portion of the paper drawing is captured by the imaging section 15. A plurality of images obtained by repeating this capturing is coupled, and thus, an image in a necessary range of the paper drawing can be automatically taken in as the drawing data.

In a case where the plurality of projection views is included in the drawing data, one projection view among the plurality of projection views is captured by the imaging section 15. In a case where a target projection view is larger than the visual field range of the imaging section 15, the control unit 110 gives an instruction to the stage drive section 12c to move the stage 12 in the horizontal direction, and then another portion of the projection view is captured by the imaging section 15. A plurality of images obtained by repeating this capturing is coupled, and thus, an image in a range corresponding to a selected projection view in the paper drawing can be automatically taken in as the drawing data. An imaging range may be determined on the basis of designation of a position on the display image corresponding to the target projection view in order to capture one projection view among the plurality of projection views. In addition, a paper drawing may be mounted such that the target projection view among the plurality of projection views is positioned within the visual field range of the imaging section 15, and the image measurement apparatus 1 may perform blob processing on the image captured by the imaging section 15 to detect a partial region of the target projection view. The image measurement apparatus 1 estimates another partial region outside the visual field range of the imaging section 15 in the target projection view on the basis of the detected partial region. The control unit 110 gives an instruction to the stage drive section 12c on the basis of the estimated other partial region to move the stage 12 in the horizontal direction, and then the other partial region of the projection view is captured by the imaging section 15. A plurality of images obtained by repeating this capturing is coupled, and thus, it is possible to automatically take an image in a range corresponding to the selected projection view as the drawing data by arranging the paper drawing so as to be positioned in the visual field range of the imaging section 15 among the paper drawings.

Therefore, even in a measurement site where only the paper drawing can be prepared, it is not necessary to scan the paper drawing with a scanner-dedicated machine in order to obtain image data, and it is possible to quickly take in the paper drawing by performing capturing by using the image measurement apparatus 1. The image measurement apparatus 1 can not only take in, as the drawing data, image data obtained by scanning the paper drawing by the scanner-dedicated machine in step SB4, but also take in, as the drawing data, the paper drawing by performing capturing by the imaging section 15 in step SB7. That is, the image measurement apparatus 1 also has a portion that directly takes in the paper drawing as the drawing data.

In addition, in step SB7, the paper drawing can be taken in as the drawing data by using a camera different from the imaging section 15. In the present embodiment, since the apparatus body 2 includes the bird's-eye view camera 17, the paper drawing mounted on the upper surface of the stage 12 can be captured by the bird's-eye view camera 17 and taken in as the drawing data. A camera other than the imaging section 15 and the bird's-eye view camera 17 may be provided, and in this case, the paper drawing can be captured by a camera other than the imaging section 15 and the bird's-eye view camera 17.

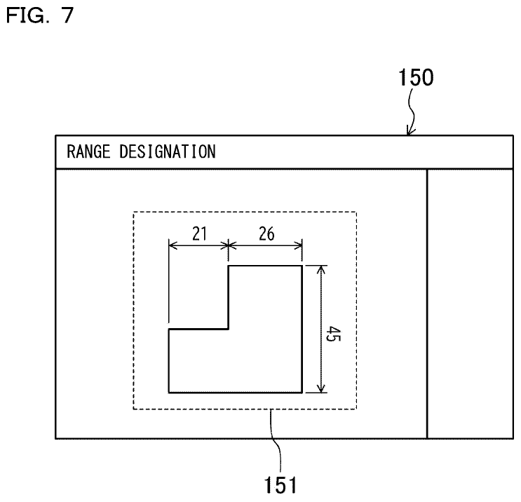

The CAD data received in step SB2 is displayed on the display section 101. For example, as illustrated in FIG. 7, the drawing intake section 111 generates a user interface screen 150 for drawing display and displays the user interface screen on the display section 101 or the like.

In step SB8, the user selects the intake range from the CAD data received in step SB2. Specifically, the user operates the mouse 104 or the like to designate a range such that a region requiring dimension measurement is the intake range while viewing the CAD data on the user interface screen 150 for drawing display displayed on the display section 101. In FIG. 7, the designated range is indicated by a rectangular frame line 151. This range designation is an intake instruction by the user. The range designation can be performed by a drag operation or the like as performed in the related art. In a case where the CAD data is two-dimensional drawing data, as illustrated in FIG. 5B, the CAD data includes a plurality of projection views such as a front view, a plan view, and a side view in which a three-dimensional stereoscopic workpiece as a measurement object is projected in parallel to a two-dimensional plane from a plurality of different directions. The user operates the mouse 104 or the like to designate a range such that a projection view requiring dimension measurement among a plurality of projection views included in the CAD data is the intake range.

As described above, the drawing intake section 111 is a portion that selectively takes in the drawing data including the workpiece shape in accordance with the intake instruction, and for example, can take in only the drawing data within a range in which the intake instruction is given by the user. In addition, the drawing intake section 111 can selectively take in the non-CAD data including the workpiece shape in accordance with the intake instruction, and can also selectively take in drawing data of a raster image including the workpiece shape and drawing data of a vector image including the workpiece shape in accordance with the intake instruction. Note that, only a part of the drawing data including the workpiece shape may be taken in, but the entire drawing data including the workpiece shape may be taken in. In a case where the drawing data includes the plurality of projection views, only the projection view requiring dimension measurement may be taken in among the plurality of projection views, or all the projection views may be taken in.

In step SB9, it is determined whether or not a scale (scaling value) can be read from the CAD data received in step SB2. In a case where the workpiece W having a shape illustrated in FIG. 6B is captured by the imaging section 15, unless binning, scaling, thinning processing, super-resolution processing, or the like is executed, the captured image and the pixels of the image data have the same scale, but the display pixels displayed on the display section 101 and the pixels of the image data may change in accordance with the scale.

Here, the scale generally refers to a reduction ratio when the drawing data is configured by a dimension reduced from an actual dimension. In the present specification, unless otherwise specified, the scale is equivalent to a measure including not only the reduction ratio but also an actual scale of an equal magnification ratio and a double scale of an enlargement ratio. The scaling value is an actual dimension per unit length of the dimension constituting the drawing data. In a case where a unit of the dimension constituting the drawing data is the same as a unit of the actual dimension, the scaling value and the scale are equivalent. In a case where the drawing data is configured by a value with a pixel position such as a pixel pitch as a reference, the scaling value depends on a conversion ratio between a dimension represented by a unit with a pixel position as a reference and a dimension constituting the drawing data, and a scale of the drawing data.

Normally, scale information is included in the CAD data, but the scale information may not be included for some reason. Thus, the measurement setting section 113 of the control unit 110 determines whether or not the scale information is included in the CAD data. In a case where the CAD data includes the scale information, the measurement setting section 113 determines YES in step SB9. In a case where the scale information is not included in the CAD data for some reason, the measurement setting section 113 determines NO in step SB9.

When NO is determined in step SB9, the processing proceeds to step SB10. In step SB10, the measurement setting section 113 acquires dimensional information included in the drawing data, and estimates the scale of the drawing on the basis of the acquired dimensional information. Processing of estimating the scaling value including the scale is called scaling estimation. The dimensional information includes a dimension and a line used for dimensioning (line for dimensioning) such as a dimension line, and in the case of the CAD data, since the dimensions and the lines used for dimensioning are associated with each other, the scale of the drawing can be estimated on the basis of the associated dimensions and the lines used for dimensioning. The line used for dimensioning includes a dimension line, a dimension auxiliary line, a lead line, and the like. For example, the scale can be estimated by comparing a value of the dimension with a length of the dimension line itself corresponding to the dimension. In addition, the measurement setting section 113 can acquire title block information of the CAD data and set a scale included in the title block information as the scale of the drawing. After step SB10, the processing proceeds to step SB14 to be described later.

In step SB11 that proceeds after the non-CAD data is received, the user selects the intake range for the non-CAD data as in step SB8. The drawing intake section 111 takes in only the drawing data within the range in which the intake instruction is given by the user.

In step SB12, the measurement setting section 113 executes vectorization on the range of the non-CAD data taken in in step SB11. For example, raster data constituted by dots is converted into vector data by vectorization, and thus, a format that can be recognized as a predetermined object such as a straight line, a circle, an arc, or the like can be obtained. The vectorization can be performed by, for example, an image processing algorithm such as Hough transform, recognition by deep learning, or the like.

In the case of the non-CAD data, even though the data is vectorized, since dimensions are not associated with a line used for dimensioning such as a dimension line as in the CAD data, the scaling estimation as described in step SB10 of FIG. 6A cannot be performed. Thus, matching is performed on the basis of OCR information of dimensions acquired by performing OCR processing on the drawing data, and intersections between dimension lines and dimension auxiliary lines of the drawing and arrow information of the dimension lines, and scaling candidates are calculated. In scaling estimation processing, corresponding dimensions and dimension lines are determined from a positional relationship between a plurality of dimensions and a plurality of dimension lines, and scaling candidates are calculated on the basis of dimension values on the basis of the OCR information of the dimensions and lengths of the dimension lines corresponding to the dimensions in the drawings. A final scaling value is calculated by performing statistical processing on a plurality of scaling candidates calculated from a plurality of dimensions and each dimension line corresponding to each dimension. For example, the scaling value is calculated on the basis of a class or a class group having a largest number in a frequency distribution of the scaling candidates. This processing is referred to as scaling estimation processing for the non-CAD data. When the scaling value is calculated, the measurement setting section 113 acquires a unit (mm, inch, or the like) of the drawing. Information regarding the unit may be designated by the user, may be acquired from a summary field included in the drawing data, or may be acquired from a character or a symbol added as a unit to the dimension.

In the case of the non-CAD data, for each coordinate on the drawing indicated by both ends of the dimension line, a unit of each coordinate value may be represented in a unit corresponding to a size of the actual drawing, or may be represented in a unit with the pixel position in the image data of the drawing as a reference. In a case where the unit of each coordinate value is represented by the unit with the pixel position as the reference, a length on the basis of the pixel position of each coordinate is converted in order to obtain the actual length in the drawing. In this case, a length between both ends of the dimension line corresponding to the actual size of the drawing can be calculated by multiplying the length between both ends of the dimension line with the pixel position as the reference by the actual length per pixel unit such as the pixel pitch. For example, the length between both ends of the dimension line corresponding to the actual size of the drawing may be calculated by converting the value obtained by multiplying the reciprocal of an image resolution pixels per inch (ppi) into units of mm.

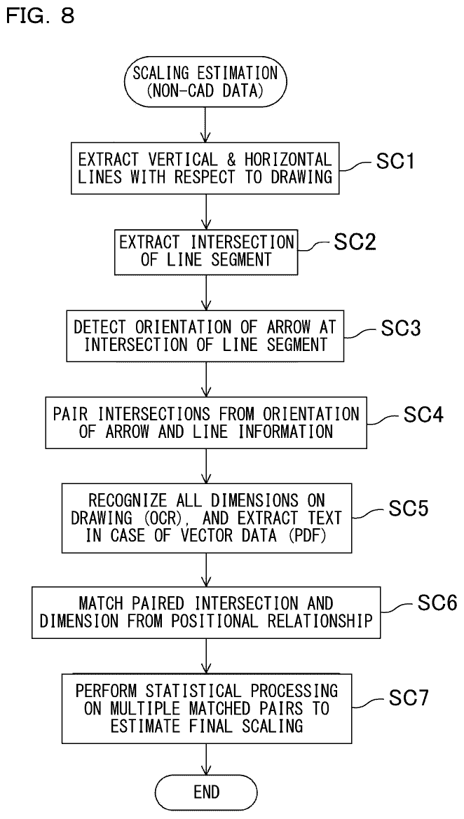

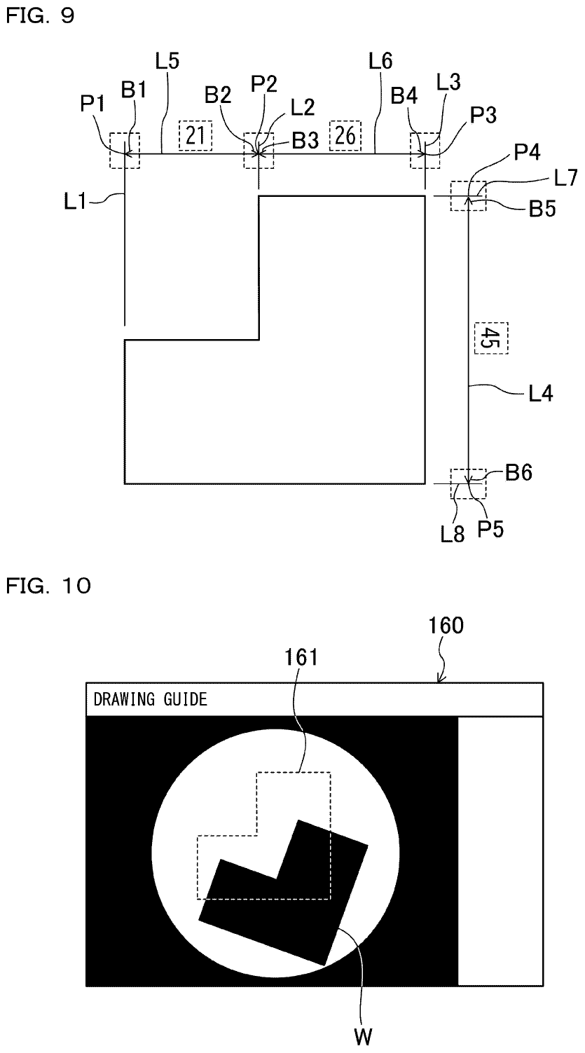

In step SB13, the measurement setting section 113 executes scaling estimation processing on the non-CAD data. In the scaling estimation processing, the measurement setting section 113 acquires the dimensional information included in the taken non-CAD data, and estimates the scale of the drawing on the basis of the acquired dimensional information. FIG. 8 illustrates details of a procedure of the scaling estimation processing for the non-CAD data. In step SC1, the measurement setting section 113 extracts vertical lines and horizontal lines with respect to the drawing on the basis of the non-CAD data. The vertical lines are lines extending in a longitudinal direction (up-lower direction) of the drawing, and the horizontal lines are lines extending in a lateral direction (left-right direction) of the drawing. Accordingly, the vertical lines and the horizontal lines are orthogonal to each other. For example, in a case where the drawing data illustrated in FIG. 9 is taken in, line segments L1, L2, L3, and L4 are extracted as the vertical lines, and line segments L5, L6, L7, and L8 are extracted as the horizontal lines. The line segments L1, L2, L3, and L7 to L8 are dimension lines, and the line segments L4 to L6 are dimension auxiliary lines. Therefore, the measurement setting section 113 recognizes the line used for dimensioning included in the drawing data taken in by the drawing intake section 111.

Note that, the drawing data illustrated in FIG. 9 is an example and has a simple workpiece shape, but many drawings include a circle, an arc, a chamfered portion, and the like. For example, a radius or a diameter is used as a dimension instruction for a circular portion or an arc portion, and a chamfered amount is instructed for a chamfered portion.

In step SC2, the measurement setting section 113 extracts points (intersections between the line segments L1 to L8) at which the plurality of line segments L1 to L8 included in the drawing intersect each other. In the case illustrated in FIG. 9, intersections P1 to P5 are extracted as the intersections.

In step SC3, the measurement setting section 113 detects orientations of arrows B1 to B6 at the intersections P1 to P5 of the line segments L1 to L8 extracted in step SC2. The arrows detected in step SC3 are arrows positioned at a distal end of the dimension line.

In step SC4, corresponding intersections on the dimension display are paired from the orientations of the arrows B1 to B6 detected in step SC3 and straight line information extracted in step SC1. In the case illustrated in FIG. 9, the arrow B1 and the arrow B2 are paired, the arrow B3 and the arrow B4 are paired, and the arrow B5 and the arrow B6 are paired.

In step SC5, the measurement setting section 113 recognizes all dimensions, tolerances, machining instructions, and the like on the drawing. A recognition method of the dimension, the tolerance, and the machining instruction is not particularly limited, but only needs to recognize a number or a predetermined symbol, and thus, for example, a method of optical character recognition (OCR) can be used. The OCR may be an OCR by machine learning.

In the case illustrated in FIG. 9, since “21”, “26”, and “45” are dimensions, the measurement setting section 113 recognizes “21”, “26”, and “45” as the dimensions. In addition, in a case where the taken drawing data is vector data (PDF), the measurement setting section 113 extracts text included in the vector data.

In step SC6, the measurement setting section 113 acquires the positions of the intersections paired in step SC4 and the positions of the dimensions recognized or extracted in step SC5, and matches the positions from a positional relationship between the paired intersections and the dimensions. In the case illustrated in FIG. 9, the intersection P1 and the intersection P2 are matched with “21” of the dimension, the intersection P2 and the intersection P3 are matched with “26” of the dimension, and the intersection P4 and the intersection P5 are matched with “45” of the dimension. As a result, the dimension and the pair of intersections are associated, and a set of the dimension and the pair of intersections is formed. As described above, the measurement setting section 113 can extract a dimensional measurement point from the drawing data and can also extract the tolerance displayed in the vicinity of the dimension.

In step SC7, the measurement setting section 113 statistically processes a plurality of sets matched in step SC6 to estimate a scaling value regarding the drawing data.

The above processing is the scaling estimation processing illustrated in FIG. 8, and when step SC7 is ended, the processing proceeds to step SB14 in FIG. 6A. In step SB14, the user mounts the workpiece W on the upper surface of the stage 12. The workpiece W mounted on the upper surface of the stage 12 is captured by the imaging section 15 and the bird's-eye view camera 17, and a live image is generated. The generated live image is displayed on the body display section 16 or the like in a state of being incorporated in a user interface screen 160 illustrated in FIG. 10, for example. At this time, a drawing guide 161 for guiding the workpiece W to a predetermined mounting place is displayed on the user interface screen 160. The drawing guide 161 is generated on the basis of the drawing data taken in by range designation, and is the same as the workpiece shape included in the drawing data. The drawing guide 161 may be generated on the basis of the drawing data taken in by the range designation and the estimated scaling value, and in this case, is the same as the workpiece shape included in the drawing data, and has a full-scale size. The live image of the workpiece W is displayed on the body display section 16 or the like at a predetermined display scale. The live image of the workpiece W and the full-scale drawing guide 161 are displayed on the body display section 16 and the like at the same display scale. The drawing guide 161 may not be exactly the same as the workpiece shape, and the drawing guide 161 may be configured by only a part of the workpiece shape. The drawing guide 161 may be configured only with the contour of the workpiece shape. The drawing guide 161 may be displayed by a line indicating a figure, or may be displayed in a color indicating a figure.

The user moves the workpiece W on the upper surface of the stage 12 while viewing the drawing guide 161 displayed on the user interface screen 160 and the workpiece W displayed as the live image, and adjusts the position of the workpiece W such that the workpiece W is arranged at the guiding position by the drawing guide 161. The user can confirm whether or not the scaling value is correct by comparing the drawing guide 161 with the live image. A position and a posture of the workpiece W are guided by the drawing guide 161, and thus, it is easy to correctly match the workpiece W in matching processing between the drawing data and the workpiece image, which is subsequent processing. The drawing guide 161 is not essential and may be omitted. In a case where the non-CAD data is taken in, the dimension and the line used for dimensioning are also drawn as a part of the drawing guide 161, but in a case where the CAD data is taken in, the drawing guide 161 is constituted only by the workpiece shape. In addition, in a case where the non-CAD data is taken in, a size of the drawing guide 161 can be adjusted. For example, in step SB13, in a case where the measurement setting section 113 estimates the scaling value regarding the drawing data, the scaling value estimated by the measurement setting section 113 is displayed on the user interface screen 160 together with the drawing guide 161 for guiding the workpiece W to the predetermined mounting place. The size adjustment of the drawing guide 161 displayed on the user interface screen 160 is executed by receiving an adjustment instruction from the user for the scaling value displayed on the user interface screen 160 and adjusting the scaling value in accordance with the adjustment instruction.

In step SB15, the imaging section 15 captures the workpiece W mounted on the upper surface of the stage 12 to generate the workpiece image. The workpiece image is stored in, for example, the storage section 120 or the like. The workpiece image may be generated in accordance with the intake instruction from the user and stored as a still image in the storage section 120 or the like. In addition, the workpiece image may be a live image which is a moving image to be displayed.

In step SB16, the matching section 114 of the control unit 110 executes matching processing of matching the workpiece shape included in the drawing data received by the drawing reception section 112 and the workpiece representation included in the workpiece image generated by the imaging section 15. As an example of the matching processing, the matching section 114 can match the workpiece shape included in the drawing data and the workpiece representation included in the workpiece image generated by the imaging section 15 by executing contour extraction processing of the workpiece W on the basis of the workpiece representation obtained by capturing the workpiece W illuminated by the transmitted illumination light emitted from the transmitted illumination section 13b by the imaging section 15 and executing contour best fit processing by using the contour of the workpiece W extracted by the contour extraction processing. Note that, the matching section 114 may acquire a coordinate system of the drawing data received by the drawing reception section 112 and a coordinate system of the workpiece image generated by the imaging section 15, and match the workpiece shape included in the drawing data and the workpiece representation included in the workpiece image generated by the imaging section 15 by the coordinate system of the acquired drawing data and the coordinate system of the workpiece image.

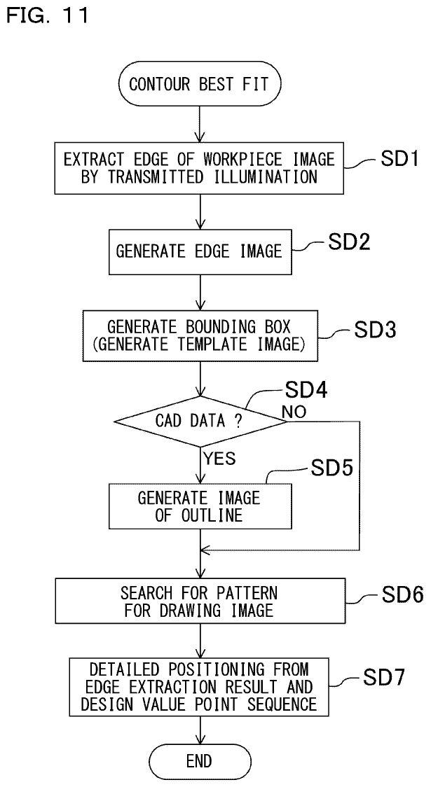

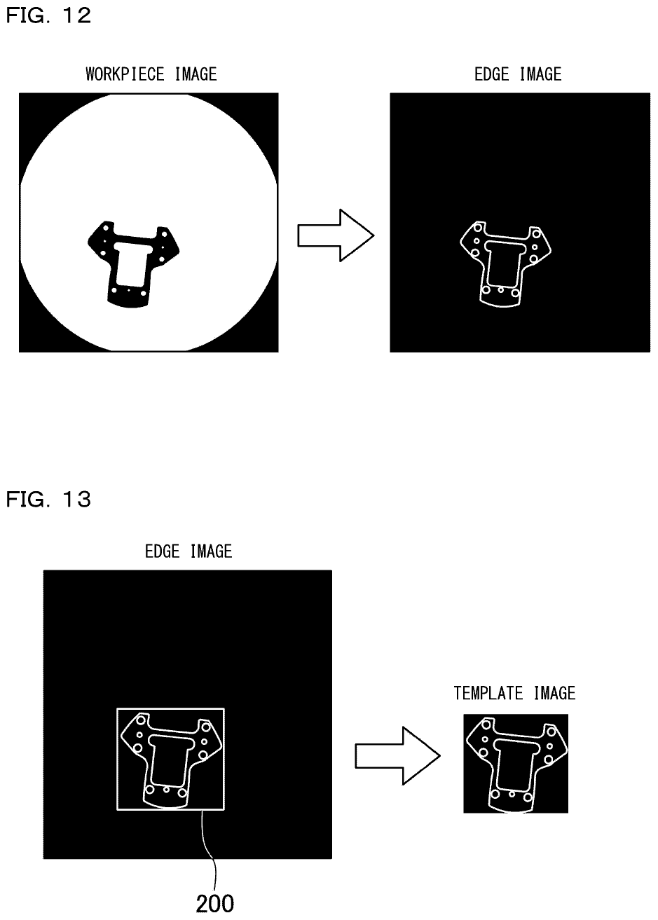

In the present embodiment, a case where the matching section 114 executes the contour best fit processing will be described. FIG. 11 is a flowchart illustrating a contour best fit processing example, and in step SD1, first, the workpiece Wis captured by the imaging section 15 in a state where the transmitted illumination light is emitted from the transmitted illumination section 13b. The workpiece image captured in the state of being irradiated with the transmitted illumination light is a so-called shadow picture, and is an image in which the workpiece Wis black and the background is white. FIG. 12 illustrates an example of the workpiece image.

A boundary portion between white and black is present in the workpiece image. A boundary portion between white and black is an edge (contour) of the workpiece W. The matching section 114 executes contour extraction processing of extracting a boundary portion between white and black, that is, an edge of the workpiece W from the workpiece image.

In step SD2, the matching section 114 generates an edge image on the basis of the edge extracted in step SD1. FIG. 12 illustrates an example of the edge image in a display form in which the background is black and the contour of the workpiece Wis white. In step SD3, as illustrated in FIG. 13, the matching section 114 generates a bounding box 200 from the edge image generated in step SD2. The bounding box 200 is indicated by a smallest rectangular frame line that can surround the contour of the workpiece W. The matching section 114 cuts out an image of a region surrounded by the bounding box 200, and uses the cut-out image as a template image. As described above, the matching section 114 executes processing of generating the template image.

In step SD4, the matching section 114 determines whether or not an inspection setting drawing taken in by the drawing intake section 111 is the CAD data. In a case where NO is determined in step SD4 and the inspection setting drawing taken in by the drawing intake section 111 is the non-CAD data, the processing proceeds to step SD6. On the other hand, in a case where YES is determined in step SD4 and the inspection setting drawing taken in by the drawing intake section 111 is the CAD data, the processing proceeds to step SD5. In step SD5, the matching section 114 extracts an outline included in the CAD data and generates an image of the outline. As a result, the contour of the workpiece shape included in the drawing data can be acquired. The CAD data, which is the inspection drawing data, is converted into image data, and thus, comparison processing between images can be applied to the workpiece image and the inspection drawing data. A conversion ratio between the actual dimension and the dimension with the pixel position in the image as the reference is equalized, and thus, the comparison processing between the images is facilitated. As illustrated in FIG. 6B, the workpiece representation of the workpiece W is projected onto the imaging element of the imaging section 15 via the optical system 15a, and the imaging section 15 generates a workpiece image corresponding to the workpiece representation. Here, in accordance with a magnification of the optical system 15a, an interval between the pixels of the imaging element, and the like, a representation of the workpiece W in a real space is projected onto a representation with the pixel position in the workpiece image. At this time, a conversion ratio between a dimension in the real space and a dimension with the pixel position in the workpiece image as the reference corresponds to the scaling value. The matching section 114 extracts the outline included in the CAD data, and generates an image of an outline corresponding to the conversion ratio between the dimension in the real space and the dimension with the pixel position in the workpiece image as the reference. As a result, the dimension in the real space and the dimension in the CAD data have the same size on the workpiece image. In a case where a drawing size in the CAD data is reduced in accordance with the scale of the CAD data, the matching section 114 generates an image of an outline having an actual drawing size on the basis of the scale information of the CAD data. In addition, when the conversion ratio between the dimension in the real space and the dimension with the pixel position in the workpiece image as the reference is changed by changing the magnification of the optical system 15a, the size of the outline included in the CAD data in the workpiece image is changed with a change of the conversion ratio.

Thereafter, the processing proceeds to step SD6, and the matching section 114 executes pattern search of a contour for the template image on the basis of the edge image of the workpiece W generated in step SD3 for the drawing image on the basis of the inspection drawing data. In the pattern search of the contour, the edge portion (contour portion) of the workpiece W coincides with the outline of the drawing data. For example, in the pattern search of the contour, the matching section 114 calculates the entire area of a white portion corresponding to an edge of the template image. Then, a position and an angle of the template image at which a ratio of an area coincident with a portion corresponding to the drawing data such as the outline included in the drawing image is the highest among a total area of the white portion of the template image are searched. In addition, in the contour pattern search, the size may be searched in addition to the position and angle of the template image. For example, the magnitude may be searched by changing the scaling value. Detailed estimation of a scaling value by pyramid search is also executed by using the result of the above-described scaling estimation as an initial solution. Note that, although the example in which the pattern search of the contour is executed on the template image on the basis of the edge image of the workpiece W and the drawing image on the basis of the inspection drawing data has been described, the present invention is not limited thereto. The pattern search of the contour of the drawing image on the basis of the inspection drawing data may be executed on the template image on the basis of the edge image of the workpiece W.

In a case where the drawing data taken in by the drawing intake section 111 is CAD data, an image of an outline is generated and pattern search of a contour is executed in step SD5. On the other hand, in a case where the drawing data taken in by the drawing intake section 111 is the non-CAD data, the pattern search of the contour is executed as the image data when the data is the image data, and the pattern search of the contour is executed after conversion into image data when the data is the non-image data. Here, in the image data used for the pattern search of the contour, a size corresponding to the actual dimension is changed on the basis of the estimated scaling value. In the case of the non-CAD data, search processing is performed on the image data including not only the outline but also a dimensional value and a line used for dimensioning. An evaluation target of a degree of coincidence of the search processing is limited to the edge portion of the template image. As a result, even though data other than the outline is included in the drawing data as a search target, when the outline matches the edge portion, it can be evaluated that the degree of coincidence is high. As described above, the matching section 114 matches the workpiece shape included in the drawing data taken in by the drawing intake section 111 with the workpiece representation included in the workpiece image generated by the imaging section 15 by processing corresponding to the type of the drawing data taken in by the drawing intake section 111.

In step SD7, the matching section 114 executes detailed positioning of the template image with respect to the drawing image from an edge extraction result of the template image and a design value point sequence (outline point sequence) of the drawing image. At this time, the template image and the drawing image are arranged at the same position, and a posture of the template image and a posture of the drawing image are the same. Further, since the scaling value is estimated, the size of the template image and the size of the drawing image can be set to be the same. That is, the matching section 114 performs matching processing of visually associating and matching the template image and the drawing image at the same position, the same size, and the same posture only by designating a range desired to be taken in by the user. This matching processing can be performed on either the CAD data or the non-CAD data.

The matching section 114 can regard a linear edge in a straight line as a linear portion of the workpiece W. In this case, the matching section 114 can match a linear portion of the workpiece shape included in the drawing data with a linear portion of the workpiece representation included in the image generated by the imaging section 15. In addition, the matching section 114 can regard a circular edge as a circular portion of the workpiece. In this case, the matching section 114 can match a circular portion of the workpiece shape included in the drawing data with a circular portion of the workpiece representation included in the image generated by the imaging section 15. In addition, the matching section 114 can regard an edge of an arc as an arc portion of the workpiece. In this case, the matching section 114 can match an arc portion of the workpiece shape included in the drawing data with an arc portion of the workpiece representation included in the image generated by the imaging section 15.

The above processing is the contour best fit processing illustrated in FIG. 11 described above. In the contour best fit processing, the coordinate systems of the workpiece image and the drawing data can be easily equalized. In addition, the drawing data of the non-image data of the CAD data and the non-CAD data is converted into the image data, and thus, the best fit processing with the edge image on the basis of the workpiece image can be performed. The coordinate systems of the workpiece image and the drawing data are equalized, and thus, visual association is performed. As a result, the setting of the measurement point for inspection and the adjustment of the inspection condition are facilitated. A drawing shape having a size corresponding to the actual dimension is formed on the basis of the scale of the drawing data and the estimated scaling value, and thus, the best fit processing with the edge image on the basis of the workpiece image can be performed. As a result, the coordinate systems of the workpiece image and the drawing data can be equalized such that the image of the workpiece W and the drawing of the workpiece W are at the same position and the same posture. In addition, as the best fit processing, searching is performed while changing the size in addition to the position and angle, and thus, the coordinate systems of the workpiece image and the drawing data can be equalized such that the image of the workpiece W and the drawing of the workpiece W have the same position, the same posture, and the same size. Note that, as the best fit processing, two-stage processing of step SD6 of coarse search and step SD7 of detailed positioning has been described, but the present invention is not limited thereto. As the best fit processing, only step SD6 of the coarse search or only step SD7 of the detailed positioning may be used.

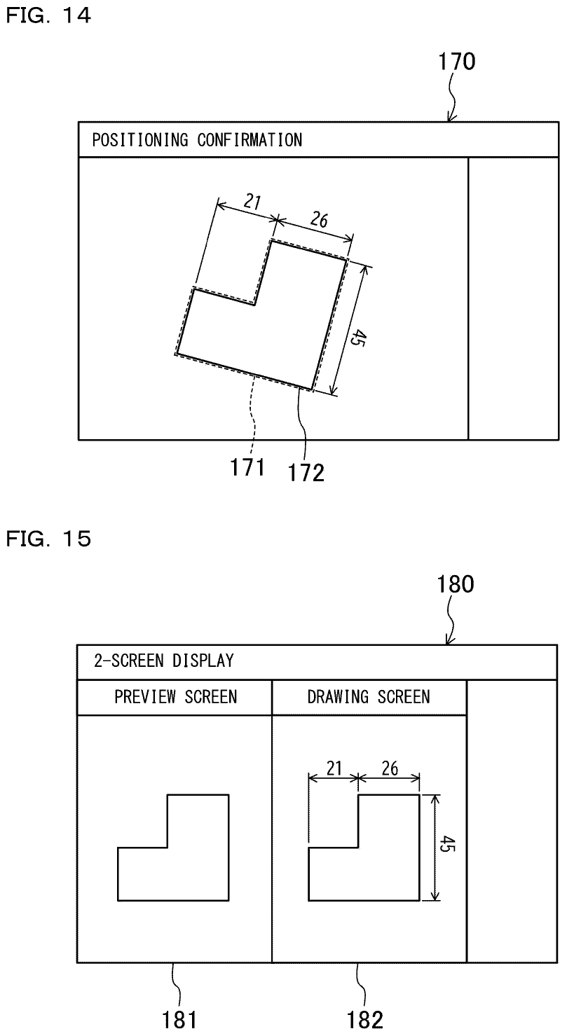

When step SD7 is ended, the processing proceeds to step SB17 in FIG. 6A. In step SB17, positioning confirmation by superimposed-drawing of the drawing and the workpiece W is performed. The display screen generation section 115 of the control unit 110 generates a user interface screen 170 illustrated in FIG. 14 and displays the user interface screen on the display section 101 or the like. On the user interface screen 170, a workpiece shape 171 included in the drawing data and a workpiece representation 172 included in the image generated by the imaging section 15 are drawn to be superimposed, and a region where the workpiece shape 171 and the workpiece representation 172 are drawn to be superimposed is referred to as a superimposed display region where the workpiece shape 171 and the workpiece representation 172 are displayed to be superimposed.

The user interface screen 170 is viewed, and thus, the user can confirm whether or not both the workpiece shape and the workpiece representation have been positioned. The user interface screen 170 is a display screen on which the workpiece shape included in the drawing data taken in by the drawing intake section 111 and the workpiece representation included in the image generated by the imaging section 15 are displayed in visual association with each other. In a case where both the workpiece shape and the workpiece representation are not positioned, the matching section 114 performs matching processing of the workpiece shape included in the drawing data and the workpiece representation included in the image generated by the imaging section 15 on the basis of a manual adjustment instruction of translation or rotation with respect to the drawing data from the user. In addition, in a case where the non-CAD data is taken in, the matching section 114 may perform matching processing of the workpiece shape included in the drawing data and the workpiece representation included in the image generated by the imaging section 15 on the basis of a manual adjustment instruction of a scaling value in addition to the translation and rotation with respect to the drawing data from the user. The user interface screen 170 displays the workpiece shape included in the manually adjusted drawing data and the workpiece representation included in the image generated by the imaging section 15 on the user interface screen 170.

In a case where the non-CAD data is taken in, the colors of the dimension and the line used for dimensioning are the same as the color of the workpiece shape 171 of the drawing data. On the other hand, in a case where the CAD data is taken in, the colors of the dimension and the line used for dimensioning are different from the color of the workpiece shape 171. Note that, this difference in the color is not essential, and the color of the dimension and the line used for dimensioning may be the same as the color of the workpiece shape 171.

In step SB18, two-screen display is performed. The display screen generation section 115 generates a user interface screen 180 having two-screen display illustrated in FIG. 15, and displays the user interface screen on the display section 101 or the like. A workpiece representation display region 181 for displaying a workpiece image captured by the imaging section 15, as a preview screen, and a drawing data display region 182 for displaying drawing data, as a drawing screen are provided on the user interface screen 180. Since the workpiece representation display region 181 and the drawing data display region 182 are arranged, the workpiece image displayed in the workpiece representation display region 181 and the drawing data displayed in the drawing data display region 182 can be compared in parallel. In short, the display screen generation section 115 generates a display screen on which the workpiece image and the drawing data can be compared in parallel and presents the display screen to the user. Note that, in a case where the non-CAD data is taken in, the colors of the dimension and the line used for dimensioning are the same as color of a line indicating the workpiece shape of the drawing data.

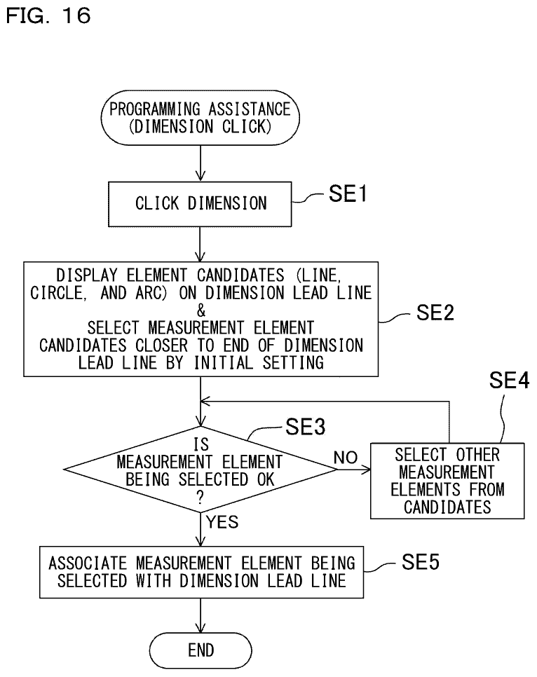

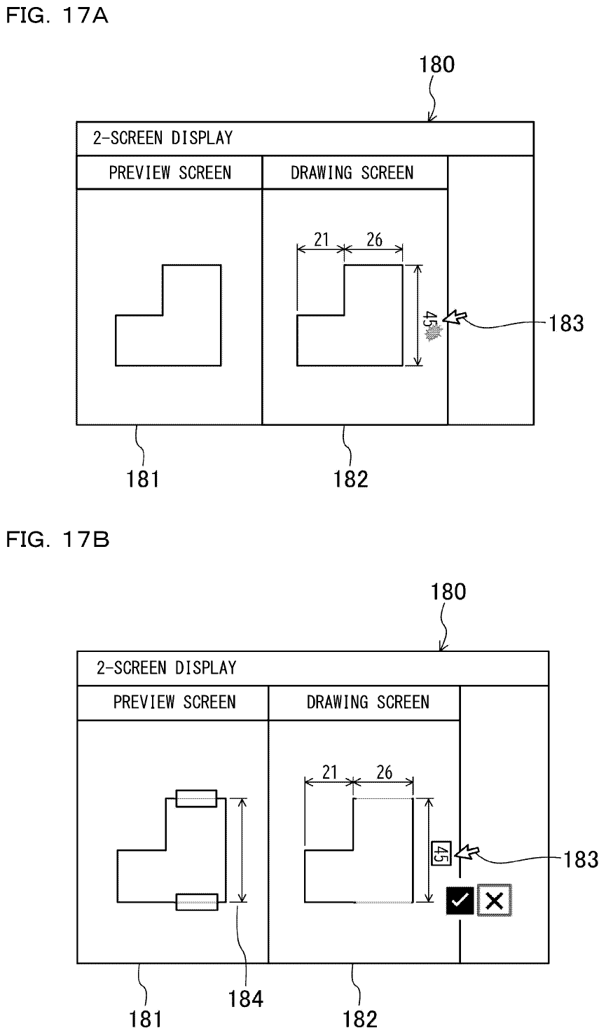

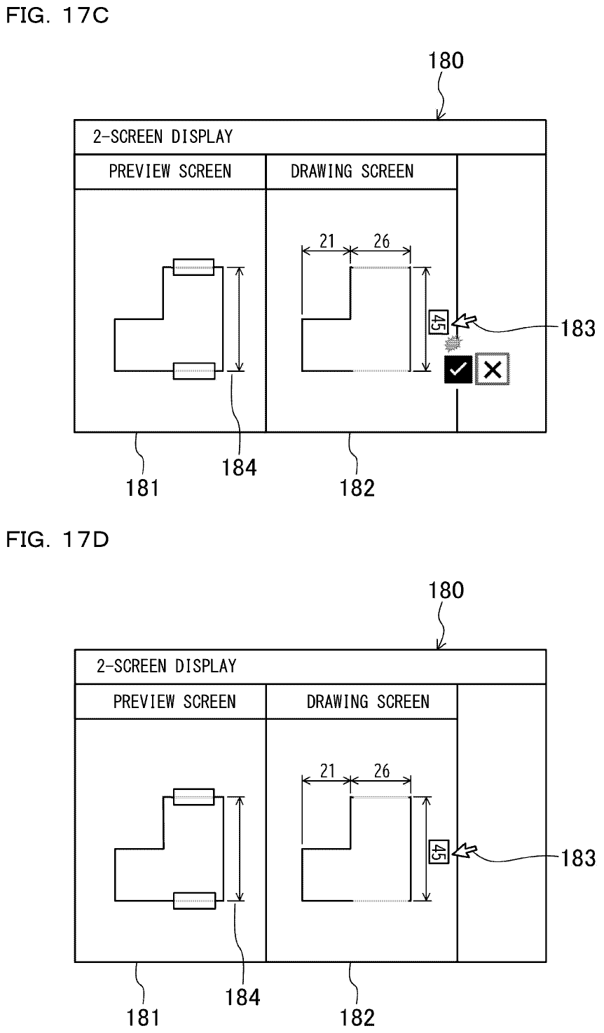

After the matching section 114 matches the workpiece shape included in the drawing data with the workpiece representation included in the image, in step SB19, programming assistance for selecting a measurement element to be associated with a dimension from information of the dimension and the line used for dimensioning and presenting the measurement element as a measurement candidate is executed. FIG. 16 is a flowchart illustrating processing of a first example of the programming assistance. In step SE1, the user clicks a dimension. For example, FIG. 17A illustrates a case where a pointer 183 is matched with dimension “45” and the mouse 104 is clicked in the drawing data display region 182 where the drawing screen is displayed. When dimension “45” is clicked, as illustrated in FIG. 17B, a measurement item 184 corresponding to dimension “45” is displayed in the workpiece representation display region 181 where the workpiece image is displayed.

In addition, as illustrated in FIG. 17C, display corresponding to the workpiece representation display region 181 can also be performed in a state where candidates for the measurement element are displayed in the drawing data display region 182 where the drawing screen is displayed. In this case, when the candidates are confirmed, the confirmed candidates are displayed as illustrated in FIG. 17D.

In addition, two candidates for the measurement element necessary for determining the measurement item 184 are displayed in the drawing data display region 182 in which the drawing screen is displayed and the workpiece representation display region 181. As two candidates of the measurement element, two straight line elements are displayed in the drawing data display region 182. In the workpiece representation display region 181, two candidates for the linear elements and a measurement range that is a target range for extracting each linear element are displayed. Similarly, when the click operation is performed with the pointer 183 matched with dimension “21”, a measurement item corresponding to dimension “21” is displayed in the workpiece representation display region 181, and two candidates for a linear element corresponding to the measurement item are displayed in the drawing data display region 182 and the workpiece representation display region 181. When the click operation is performed with the pointer 183 matched with dimension “26”, a measurement item corresponding to dimension “26” is displayed in the workpiece representation display region 181, and two candidates for a linear element corresponding to the measurement item are displayed in the drawing data display region 182 and the workpiece representation display region 181. In FIG. 17A, although the dimension of the straight line is illustrated, for example, for a circle, an arc, or the like, the measurement item corresponding to the workpiece representation display region 181 and the candidates for the measurement element are displayed by performing the click operation while the pointer 183 is similarly positioned. The user can change the candidates for the measurement element displayed in the drawing data display region 182. In selecting the measurement item and displaying a pair of candidates for the measurement element, when the click operation is performed by matching the pointer 183 with another measurement element, the measurement element selected by the click operation is displayed as the candidate for the measurement element, and a measurement element corresponding to the same dimensional auxiliary line as the selected measurement element, of the pair of candidates for the measurement element, is removed from the candidates. The measurement element and the measurement range displayed in the workpiece representation display region 181 are changed to correspond to the drawing data display region 182.

As described above, when an instruction of the measurement item is received on the drawing data displayed in the drawing data display region 182, the measurement setting section 113 can reflect the measurement item for which the instruction is received on the drawing data, the measurement element corresponding to the measurement item, and the measurement range corresponding to the measurement element on the workpiece representation displayed in the workpiece representation display region 181. In addition, the user does not need to be conscious of which measurement element such as a straight line, a circle, or an arc is to be generated, and the image measurement apparatus 1 automatically generates an appropriate measurement element. The generated measurement element is stored in the storage section 120 or the like. The same applies hereinafter. Note that, the measurement element is also called an element tool, and includes a measurement range corresponding to a shape and a position of the element to be measured.

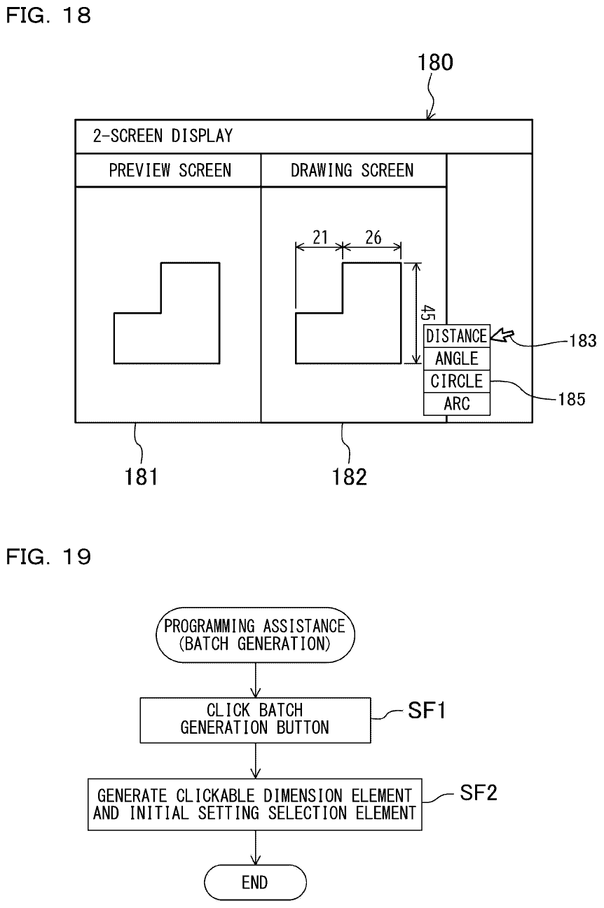

In the case of the CAD data, the dimension is an attribute dimension having attributes such as a distance, an angle, a circle diameter, and a radius of curvature. The measurement setting section 113 selects a measurement element on the basis of an attribute of a dimension regarding a measurement position read from the CAD data. The measurement setting section 113 executes setting of each measurement element including a measurement range corresponding to a shape and a position for each selected measurement element. In addition, the measurement setting section 113 executes setting of a setting item using each selected measurement element. In a case where the dimension does not have attributes such as a distance, an angle, a circle diameter, and a radius of curvature even in the CAD data, as illustrated in FIG. 18, when the measurement item is selected by the user, a candidate presentation window 185 is displayed on the user interface screen 180. In the candidate presentation window 185, candidates for the attribute corresponding to the dimensional information designated by the user are displayed. In this example, a case where “distance”, “angle”, “circle”, and “arc” are displayed as candidates for the attribute of the dimension is illustrated, but one or two or more of these candidates may be displayed in the candidate presentation window 185. In addition, similarly in the case of the non-CAD data, since the attribute of the dimension is unknown, as illustrated in FIG. 18, when the measurement item is selected by the user, the candidate presentation window 185 is displayed on the user interface screen 180. In the candidate presentation window 185, the candidates for the attribute corresponding to the dimensional information designated by the user are displayed. As described above, the candidates for the attribute of the dimension are displayed in the candidate presentation window 185, and thus, the candidates for the measurement element can be presented to the user.

The user designates and selects a suitable measurement element among the candidates for the measurement element displayed in the candidate presentation window 185. For example, when the mouse 104 is clicked while the pointer 183 is matched with a measurement element to be designated, the measurement element to which the pointer 183 is matched is designated and selected. As described above, the measurement element selection section 116 can present the candidates for the measurement element corresponding to the dimensional information and select the measurement element from the candidates according to designation by the user.

The operation of clicking the pointer 183 according to the dimension is an operation of giving instructions of the measurement position and the measurement item in the workpiece shape included in the drawing data. A position of the pointer 183 and an operation state of the mouse 104 are detected, and thus, the measurement setting section 113 receives the instructions of the measurement position and the measurement item in the workpiece shape from the user. When the instruction of the measurement position is received, the measurement setting section 113 can receive the instruction by an element tool such as a line, a circle, or an arc.

The measurement setting section 113 receives the instructions of the measurement position and the measurement item from the user, and reflects the measurement position and the measurement item, as a measurement position and a measurement item for the workpiece representation generated by the imaging section 15. When the instructions of the measurement position and the measurement item are received, the measurement setting section 113 can receive, as the instruction of the measurement item, a dimension between two straight lines which are measurement elements, a separation dimension between a circle and a circle, a separation dimension between a circle and a straight line, an angle of an arc, an angle of an inclined surface, and the like. The measurement setting section 113 can receive not only the above-described dimension designation but also tolerance designation included in the drawing.

The measurement setting section 113 can receive the instruction of the measurement item from the user on the drawing data displayed in the superimposed display region of the user interface screen 170 by one-screen superimposed display illustrated in FIG. 14 instead of the two-screen display illustrated in FIG. 15, for example. When the instruction of the measurement item is received on the drawing data displayed in the superimposed display region, the measurement setting section 113 reflects the measurement item on the workpiece representation displayed in the superimposed display region.

Note that, the measurement setting section 113 may receive the instruction of the measurement position or the measurement item in the workpiece shape included in the drawing data and reflect the measurement position or the measurement item as the measurement position or the measurement item with respect to the workpiece representation. For example, it is possible to receive only the instruction of the measurement position in the workpiece shape or only the instruction of the measurement item. In a case where only the instruction of the measurement position is received, the measurement position with respect to the workpiece representation can be reflected. In a case where only the instruction of the measurement item is received, the measurement item for the workpiece representation can be reflected.

The measurement position or the measurement item is reflected on the workpiece representation, and thus, the measurement position or the measurement item is set on the workpiece representation. The measurement setting section 113 can set only one measurement position or a plurality of measurement positions for the workpiece representation included in the image generated by the imaging section 15. For the measurement item, the measurement setting section 113 can also set only one measurement item or a plurality of measurement items for the workpiece representation included in the image generated by the imaging section 15. As described above, the measurement setting section 113 can set, as the measurement element, at least one of the plurality of measurement positions or one or more measurement items for the workpiece representation.

The measurement element selection section 116 of the control unit 110 can receive designation of a position of the dimensional information in the drawing data taken in by the drawing intake section 111. The position of the dimensional information in the drawing data is designated by the user, and for example, an operation of clicking the dimension by the user in step SE1 of FIG. 16 corresponds to the designation of the position of the dimensional information. The designation of the position of the dimensional information in the drawing data may be an operation of the user who clicks a line used for dimensioning, such as a dimension line, a dimension auxiliary line, or a lead line. When the designation of the position of the dimensional information in the drawing data is received, the measurement element selection section 116 selects the measurement element corresponding to the dimensional information. When the measurement element is selected by the measurement element selection section 116, the measurement setting section 113 reflects the measurement position and the measurement item for the workpiece representation on the basis of the measurement element corresponding to the dimensional information and the measurement item corresponding to the dimensional information. The data generation section 118 of the control unit 110 generates measurement setting data on the basis of the measurement position and the measurement element reflected by the measurement setting section 113. The measurement setting data generated by the data generation section 118 is stored in, for example, the storage section 120 or the like.

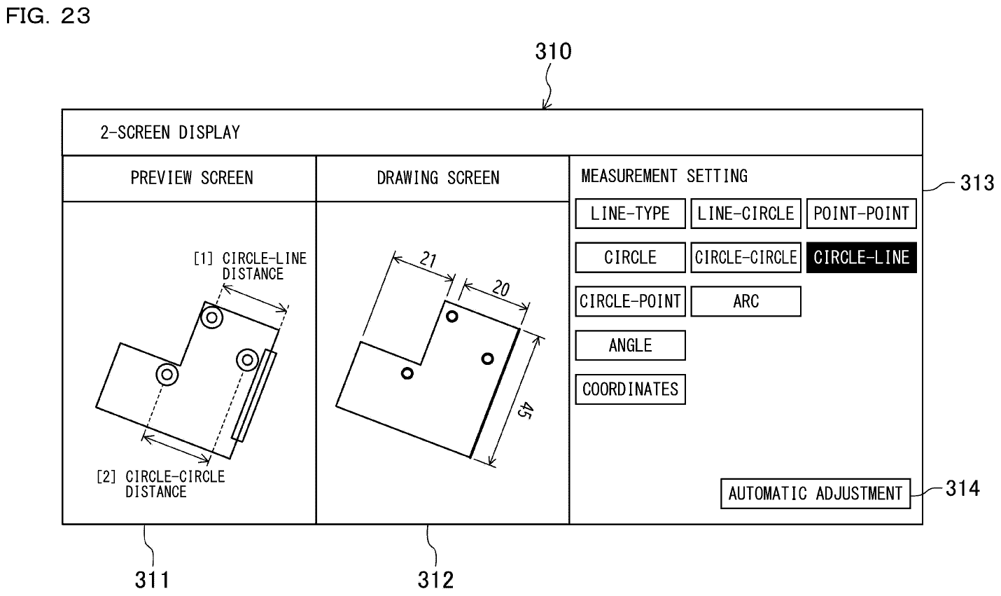

In step SE2, the measurement element selection section 116 presents candidates for the measurement element corresponding to the dimensional information, and selects the measurement element from the candidates according to the designation by the user. Specifically, as illustrated in FIG. 23, a pair of measurement elements positioned close to each dimension auxiliary line among a pair of measurement elements corresponding to the dimension auxiliary line corresponding to the dimension is presented as the candidates. As described above, the measurement element selection section 116 can present the candidates for the measurement element corresponding to the dimensional information and select the measurement element from the candidates according to designation by the user. In addition, the measurement element selection section 116 may automatically select an element candidate close to an end of the dimensional auxiliary line or the lead line in initial setting.

In step SE3, the user determines whether or not the measurement element being selected is acceptable. In a case where NO is determined in step SE3, the processing proceeds to step SE4, and the user designates and selects another measurement element from the candidates. In a case where YES is determined in step SE3, the processing proceeds to step SE5, and the measurement element being selected is associated with the measurement item including the dimension.

Specifically, the measurement element selection section 116 identifies attributes of the dimension and the line used for dimensioning. For example, in the case of the CAD data, since the CAD data has identification information capable of identifying an outline, a line used for dimensioning, a dimension, and the like, the measurement element selection section 116 can automatically identify the attributes of the dimension and the line used for dimensioning by using the identification information. After the attributes of the dimension and the line used for dimensioning are identified, the measurement element selection section 116 automatically associates the dimension with the line used for dimensioning corresponding to the dimension.

As described above, the associating section 119 of the control unit 110 executes associating processing of associating the measurement setting data with the workpiece representation visually associated with the workpiece shape included in the drawing data. In addition, the associating section 119 can also associate the workpiece shape included in the drawing data taken in by the drawing intake section 111 with the measurement setting data for the workpiece representation included in the image generated by the imaging section 15. The measurement setting data is data generated on the basis of the measurement position and the measurement element.

FIG. 19 is a flowchart illustrating processing of a second example of the programming assistance. The second example is an example that can be used in a case where the CAD data is taken in, and in the second example, in a case where there is a plurality of measurement elements, the measurement elements can be generated in a batch manner. In step SF1, the user clicks a batch generation button (not illustrated) displayed on the display section 101 or the like with the mouse 104. In step SF2, the measurement setting section 113 generates a clickable dimension element and a selection element of the initial setting. The clickable dimension element is a dimension clickable by the user as described in step SE1 illustrated in FIG. 16. The selection element of the initial setting is a measurement element selected in the initial setting of step SE2 illustrated in FIG. 16. As a result, a plurality of measurement elements can be automatically generated.

In the batch generation, since all the measurement elements are generated without reflecting the user's intention, there may be a case where a measurement element unnecessary for the user is generated or a case where a measurement element intended by the user is not generated. In such a case, the programming assistance of the first example illustrated in FIG. 16 may be used. That is, it is possible to delete unnecessary elements after the measurement element batch generation or change the element candidate extracted from the information of the dimensional auxiliary line of the measurement element.

### (Automatic Adjustment Function)

The image measurement apparatus 1 has an automatic adjustment function of automatically adjusting a plurality of measurement conditions. In the image measurement apparatus of the related art, it is necessary for the user to adjust the measurement conditions including a type of the camera, a type of the illumination, a position of the camera, parameters of the image processing, and the like in addition to setting the measurement point and the measurement content. However, in the image measurement apparatus 1 according to the present embodiment, the automatic adjustment section 117 for automatically executing such adjustment is provided in the control unit 110.

The automatic adjustment section 117 is a section that automatically adjusts a measurement condition for extracting each measurement element corresponding to each measurement position or measurement item designated by the measurement setting section 113 for every measurement element. The measurement conditions include a plurality of measurement conditions such as an illumination condition of the illumination section 13, an imaging condition of the imaging section 15, and an edge extraction condition in the edge extraction processing executed by the measurement section 110A. In the present embodiment, the automatic adjustment section 117 automatically adjusts the illumination condition of the illumination section 13, the imaging condition of the imaging section 15, and the edge extraction condition, but may automatically adjust at least one of the illumination condition of the illumination section 13, the imaging condition of the imaging section 15, and the edge extraction condition. An automatic adjustment result by the automatic adjustment section 117 includes the illumination condition of the illumination section 13, the imaging condition of the imaging section 15, and the edge extraction condition, which are stored in the storage section 120 or the like.

The illumination condition of the illumination section 13 includes, for example, an illumination type, an illumination height, and the like. The illumination condition of the illumination section 13 includes switching of the epi-illumination section 13a, the transmitted illumination section 13b, and the ring illumination section 13c. In addition to the epi-illumination section 13a, the transmitted illumination section 13b, and the ring illumination section 13c, the illumination type includes a slit ring illumination section (not illustrated) and the like, and also includes multi-angle illumination for illuminating from a plurality of directions, illumination from the near side, illumination from the far side, illumination from the left side, illumination from the right side, and the like. Further, the illumination type may include a plurality of types of illumination having different illumination colors. The switching of the illumination type is included in the illumination condition of the illumination section 13.

The illumination section 13 can adjust the amount of light, an illumination time, and the like of each illumination, and for example, the amount of light and the illumination time of the epi-illumination section 13a, the amount of light and the illumination time of the transmitted illumination section 13b, and the like are included as the illumination conditions of the epi-illumination section 13a or the transmitted illumination section 13b. In addition, the illumination height includes illumination from a high position and illumination from a low position for the workpiece W, and the height of the illumination can also be adjusted.

The imaging condition of the imaging section 15 includes, for example, at least one of an exposure time, a magnification of the optical system 15a included in the imaging section 15, a diaphragm of the optical system 15a included in the imaging section 15, and a height of the imaging section 15 from the stage 12. Since a size of the imaging visual field changes by adjusting the magnification of the optical system 15a, it can be said that the size of the imaging visual field is included in the imaging condition of the imaging section 15. The imaging section 15 can be configured to be able to switch between, for example, a high-accuracy measurement mode with a narrow visual field and a wide visual field measurement mode with a wide visual field by changing the magnification of the optical system 15a. Further, the imaging section 15 can also be configured to be able to switch between, for example, a first high-accuracy measurement mode in which the diaphragm is opened and a second high-accuracy measurement mode in which the diaphragm is narrowed by changing the diaphragm of the optical system 15a.

The height of the imaging section 15 from the stage 12 can be adjusted by moving the stage 21 in the Z direction by the stage drive section 12c.

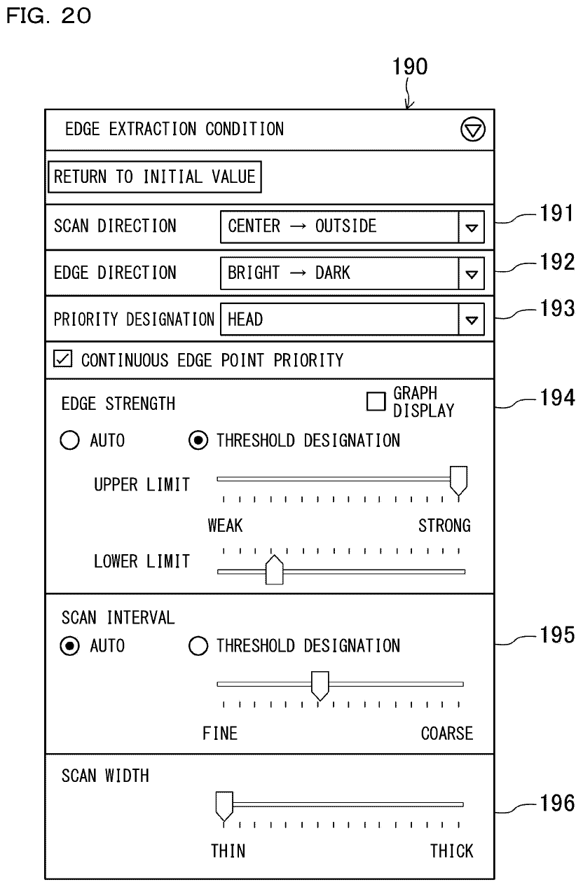

Here, the edge extraction processing executed by the measurement section 110A will be described. The edge extraction condition applied at the time of edge extraction processing includes at least one of a scan direction, an edge direction, priority designation, an edge strength threshold, a scan interval, and a scan width. FIG. 20 is a diagram illustrating an edge extraction condition setting window 190 displayed at the time of edge extraction condition setting. For example, a scan direction setting region 191, an edge direction setting region 192, a priority designation region 193, an edge strength threshold setting region 194, a scan interval setting region 195, a scan width setting region 196, and the like are provided in the edge extraction condition setting window 190. In the scan direction setting region 191, it is possible to set whether to scan from a center toward an outside of the edge extraction region, to scan from the outside toward the center, or the like. In the edge direction setting region 192, it is possible to set whether to extract a portion changing from a bright portion to a dark portion as an edge or to extract a portion changing from a dark portion to a bright portion as an edge. In the priority designation region 193, for example, the maximum, the head, and the like can be set. In the edge strength threshold setting region 194, it is possible to set a threshold at the time of extraction as the edge, and it is also possible to automatically set the threshold. In the scan interval setting region 195, the scan interval at the time of extracting the edge can be set, and the scan interval can also be automatically set. In the scan width setting region 196, a scan width at the time of extracting the edge can be set.

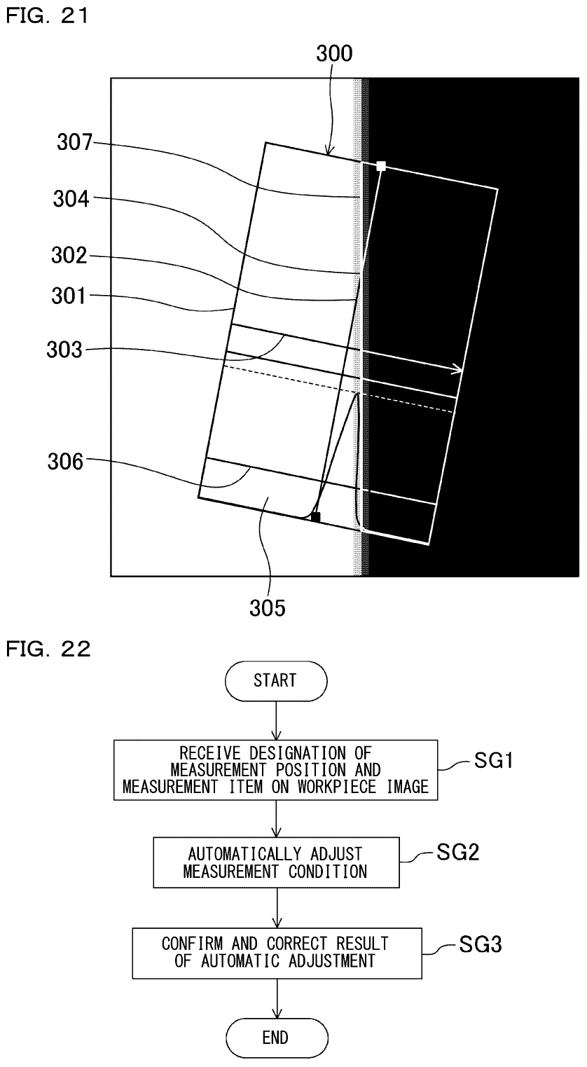

FIG. 21 is a diagram for explaining the edge extraction processing executed by the measurement section 110A. The user designates a measurement position and a measurement item for a shape feature on the workpiece image. In the example illustrated in FIG. 21, an example in which a measurement area 300 is arranged to be superimposed on the workpiece image is illustrated. The measurement area 300 includes a scan area 301 that defines an area where the edge extraction processing is executed and an area center line 302 indicating a center of the scan area 301 in a width direction.

When the measurement section 110A executes the edge extraction processing, a pixel value on the scan line 303 perpendicular to the area center line 302 is acquired, and a position of an edge point 304 is calculated on the basis of the acquired pixel value. An edge strength graph 305 is obtained by differentiating pixel values on the scan line 303 side by side in an extending direction of the scan line 303, and the measurement section 110A generates the edge strength graph 305.

The measurement section 110A generates the edge point 304 at a position on the scan line 303 where the edge strength graph 305 takes an extreme value. Although there may be a plurality of extreme values on the edge strength graph 305, it is possible to set which extreme value to select. Here, a method in which an edge strength lower limit threshold 306 is set, the extreme value on the edge strength graph 305 is viewed along the extending direction of the scan line 303, and the extreme value at which strength exceeds the edge strength lower limit threshold 306 for the first time is selected is adopted. By this method, one edge point 304 is generated from one scan line 303. A plurality of edge points 304 are generated by performing this processing on a plurality of scan lines 303, a line 307 in which the edge points are fitted is calculated, and the line 307 is set as an edge. Circles and arcs are similarly acquired.

Next, a flow of automatic adjustment by the automatic adjustment section 117 will be described. FIG. 22 is a flowchart illustrating a flow of automatic adjustment by the automatic adjustment section 117, and in step SG1, the automatic adjustment section 117 receives, as the measurement elements, the measurement position and the measurement item designated on the workpiece image by the user. For example, a setting user interface screen 310 illustrated in FIG. 23 is generated by the display screen generation section 115 and displayed on the display section 101 or the like. A workpiece representation display region 311 for displaying the workpiece image, a drawing data display region 312 for displaying the drawing data, and a measurement setting region 313 are provided on the setting user interface screen 310. In the measurement setting region 313, for example, a measurement tool for measuring a distance between a line and a line, a distance between a line and a circle, a distance between a point and a point, a distance between a circle and a circle, and the like, a measurement tool for measuring an angle, and the like are displayed. The example illustrated in FIG. 23 illustrates a case where the distance between the circle and the line and the distance between the circle and the circle are measured, and the measurement position can be automatically indicated by the drawing data displayed in the drawing data display region 312, or can be indicated by the user on the workpiece image displayed in the workpiece representation display region 311. When the instructions of the measurement position and the measurement item are received by the automatic adjustment section 117, “[1] circle-line distance” is displayed in the workpiece representation display region 311 as the measurement tool for measuring the distance between the circle and the line, and “[2] circle-circle distance” is displayed in the workpiece representation display region 311 as the measurement tool for measuring the distance between the circle and the circle.

An automatic adjustment button 314 is provided on the setting user interface screen 310. When the user presses the automatic adjustment button 314 after the instructions of the measurement position and the measurement item are ended, the processing proceeds to step SG2 illustrated in FIG. 22, and the automatic adjustment section 117 automatically adjusts the illumination condition, the imaging condition, and the edge extraction condition for every measurement element. As described above, the automatic adjustment section 117 automatically adjusts a plurality of types of measurement conditions when the instruction of the measurement item on the workpiece image or the drawing data is received. In a case where the plurality of measurement positions is received as illustrated in FIG. 23, the automatic adjustment section 117 can automatically adjust the plurality of types of measurement conditions for the plurality of measurement positions in a batch manner.

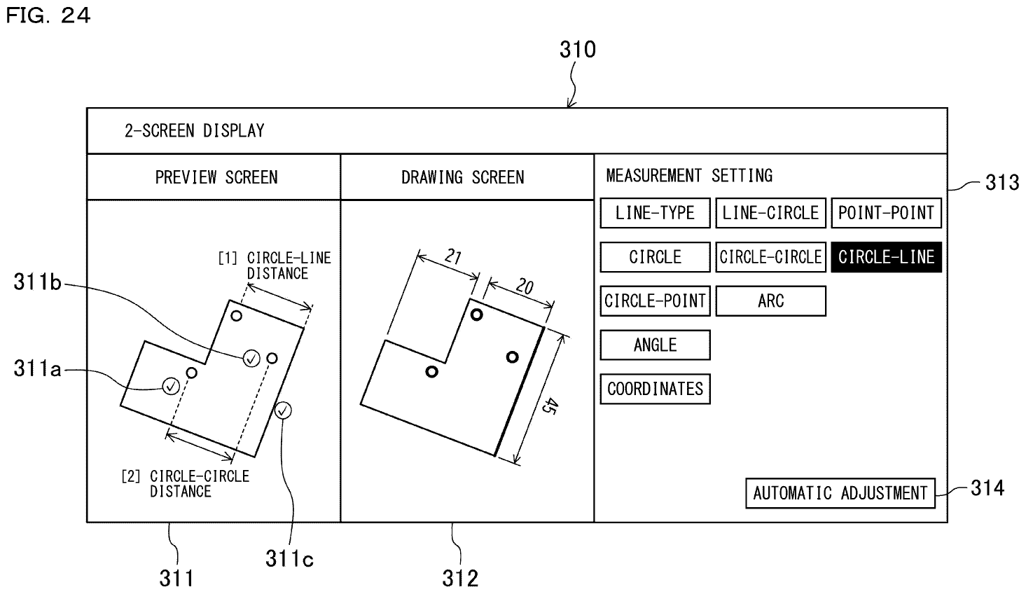

After the automatic adjustment section 117 executes the automatic adjustment, as illustrated in FIG. 24, first to third icons 311a, 311b, and 311c indicating the automatically adjusted measurement element are displayed in the workpiece representation display region 311 of the setting user interface screen 310. The display screen generation section 115 displays the first to third icons 311a, 311b, and 311c in the workpiece representation display region 311. Display positions of the first to third icons 311a, 311b, and 311c are in the vicinity of the automatically adjusted measurement element, and thus, the user can grasp which measurement element measurement condition is automatically adjusted or which measurement element measurement condition is not automatically adjusted only by viewing the workpiece representation display region 311. Instead of the first to third icons 311a, 311b, and 311c, or in addition to the first to third icons 311a, 311b, and 311c, characters or symbols indicating the automatically adjusted measurement elements may be displayed. In addition, the display screen generation section 115 may generate a display screen that displays the measurement element for which the measurement condition is automatically adjusted and the measurement element for which the measurement condition is not automatically adjusted in different aspects.

Thereafter, the processing proceeds to step SG3 illustrated in FIG. 22, and the user confirms and corrects the result of the automatic adjustment. Specifically, among the first to third icons 311a, 311b, and 311c, an icon corresponding to the measurement element that the user wants to confirm is selected. Examples of an operation of selecting the icon include an operation of clicking the icon.

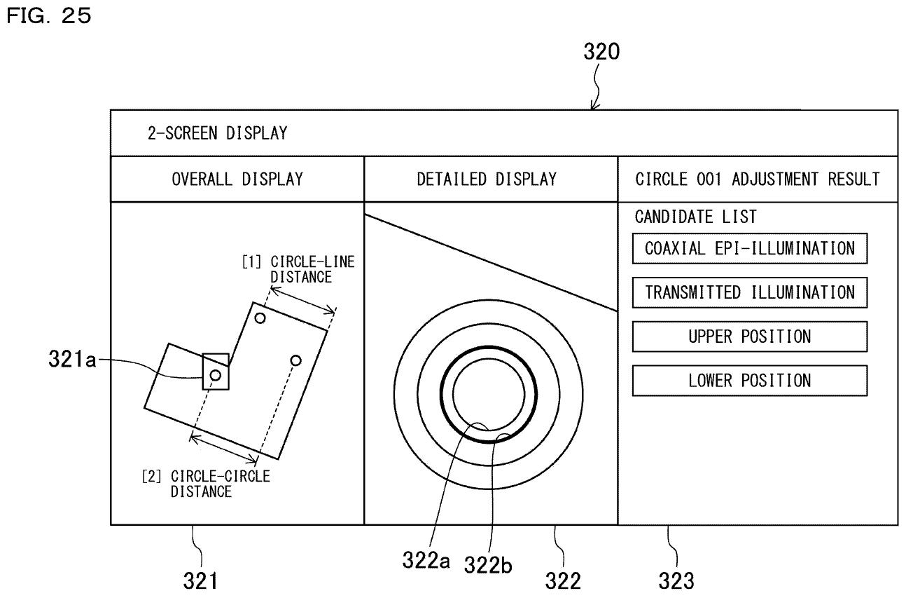

In a case where the first icon 311a is selected, the display screen generation section 115 generates a user interface screen 320 of the detailed display illustrated in FIG. 25 and displays the user interface screen on the display section 101 or the like. A workpiece representation display region 321 for displaying the workpiece image, a detailed display region 322, and an adjustment result display region 323 are provided on the user interface screen 320 for detailed display. In the detailed display region 322, a partially enlarged image of the workpiece image displayed in the workpiece representation display region 321 is displayed. In this example, since the icon 311a of FIG. 24 is selected, a portion including the measurement element (circle) corresponding to the icon 311a is displayed, as an enlarged image, in the detailed display region 322. The range displayed in the detailed display region 322 is indicated by a frame line 321a in the workpiece representation display region 321. In the detailed display region 322 of FIG. 25, the automatic adjustment section 117 displays the measurement element extracted as the measurement element corresponding to the measurement position. The measurement element extracted by the automatic adjustment section 117 is, for example, at least one of a line, a circle, and an arc. When the measurement element is extracted, the automatic adjustment section 117 extracts the measurement element on the basis of an edge extracted in an element tool such as a dimension. A color not actually included in the workpiece image is displayed to be superimposed on the workpiece image, and thus, it is possible to cause the user to grasp the portion extracted as the edge.

In addition, in a case where the second icon 311b of FIG. 24 is selected, a portion including the measurement element (circle) corresponding to the second icon 311b is displayed, as an enlarged image, in the detailed display region 322. In a case where the third icon 311c is selected, a portion including the measurement element (line) corresponding to the third icon 311c is displayed, as an enlarged image, in the detailed display region 322. As described above, the display screen generation section 115 generates the display screen displaying whether or not the edge is extracted by the measurement section 110A for every measurement element.

The user confirms the partially enlarged image displayed in the detailed display region 322, and completes the automatic adjustment when the portion extracted as the edge is correct. When the automatic adjustment is completed, the data generation section 118 generates measurement setting data on the basis of the measurement position and the measurement element, and the measurement condition automatically adjusted by the automatic adjustment section 117.

On the other hand, when the portion extracted as the edge is wrong, the correction can be performed. In the adjustment result display region 323, candidates for other illumination conditions are listed. That is, erroneous extraction of the edge under a currently selected illumination condition is considered to be suitable for extracting the edge under an illumination condition other than the currently selected illumination condition. In this case, the other illumination conditions are presented as the candidates for the illumination condition to the user, and thus, the user can select an illumination condition suitable for extracting the edge. When the user selects a certain illumination condition from among the candidates for the illumination condition displayed in the adjustment result display region 323, the illumination condition candidate is received by the measurement setting section 113. The measurement setting section 113 applies the received illumination condition to cause the imaging section 15 to generate the workpiece image. The measurement section 110A executes the edge extraction processing on a new workpiece image generated by the imaging section 15.

In the above-described example, the candidates for the illumination condition are presented to the user, but the present invention is not limited thereto, and the candidates for the imaging condition and the candidates for the edge extraction condition can also be presented to the user. As described above, the automatic adjustment section 117 presents other measurement condition candidates of the same type, and receives selection of the measurement condition candidate by the user. The same type is, for example, a measurement condition classified into the illumination condition, a measurement condition classified into the imaging condition, and a measurement condition classified into the edge extraction condition.

When the portion extracted as the edge is wrong, the automatic adjustment section 117 receives an input of the edge position by the user on the image generated by the imaging section 15, and can automatically adjust the measurement condition such that an edge similar to the edge position at which the input is received is extracted. For example, in the detailed display region 322 of FIG. 25, an example in which a second circle 322b from an innermost circle 322a is extracted as an edge is illustrated, but in a case where a correct edge is the innermost circle 322a, the user inputs an operation of designating the innermost circle 322a. For example, three points on the innermost circle 322a are clicked, and thus, it is determined that the circle 322a is the edge position, and the automatic adjustment section 117 receives the input by the user. In this case, the automatic adjustment section 117 adjusts the illumination condition, the imaging condition, and the edge extraction condition such that the circle 322a is extracted as the edge. The same applies to the case of the line or the arc.

Note that, in a case where the portion extracted as the edge is wrong, the user can manually adjust the illumination condition, the imaging condition, and the edge extraction condition.

When there are a plurality of portions extracted as edges, the image measurement apparatus 1 can be operated in a mode in which the user can designate the portions extracted as the edges one by one and confirm and correct the portions, or the image measurement apparatus 1 can be operated in a mode in which all the measurement elements can be continuously confirmed and corrected. This mode switching can be performed by the user.

### (Logic of Automatic Adjustment)

Next, a specific logic of the automatic adjustment by the automatic adjustment section 117 will be described. As illustrated in FIG. 23, the automatic adjustment section 117 starts the automatic adjustment from a state where the measurement position and the measurement item are designated by the user. In the following description, for the sake of convenience, among the illumination conditions, transmitted illumination and other illumination are distinguished, and all illuminations other than the transmitted illumination are referred to as epi-illuminations. In the case of the transmitted illumination, since a state like a so-called shadow picture is obtained, edge detection is relatively easy. On the other hand, in the case of the epi-illumination, since the edge position varies depending on a focal position and a state of the illumination or the edge position varies due to the edge extraction processing of selecting a target edge from among a plurality of edge candidates, adjustment is difficult.

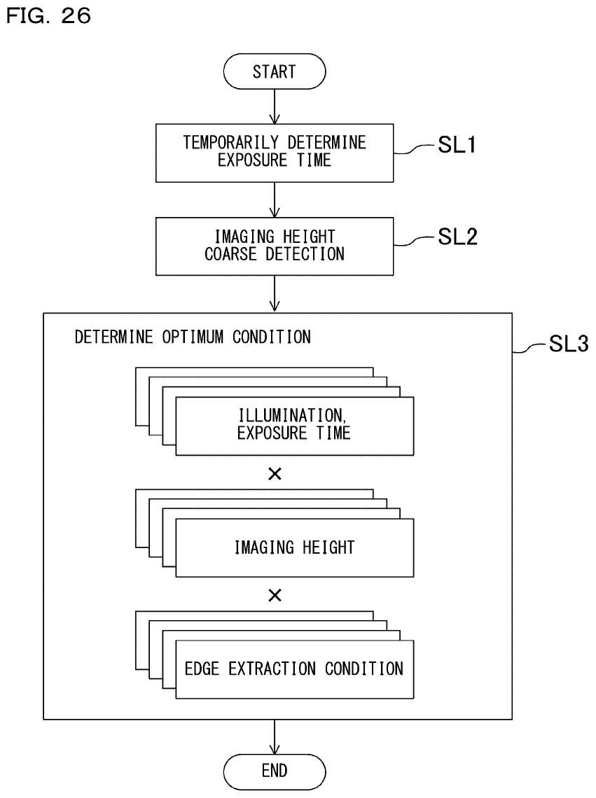

FIG. 26 is an automatic adjustment flowchart, and illustrates an automatic adjustment flowchart for a measurement element in which each condition is determined for every measurement element and epi-illumination is determined to be used as the illumination condition. In step SL1, the automatic adjustment section 117 performs automatic exposure adjustment on a target measurement element. By the automatic exposure adjustment, at least one of parameters regarding the brightness of the obtained workpiece image, such as the exposure time of the imaging section 15, the brightness of the epi-illumination, and a gain for the workpiece image data, is temporarily determined. In step SL2, the workpiece image is acquired on the basis of the parameters provisionally determined in step SL1, and the automatic adjustment section 117 coarsely detects a height of the stage 12, that is, imaging heights of the measurement element of the workpiece W and around the measurement element. The coarse detection acquires a height profile of the measurement element and around the measurement element. After step SL2, a search is performed while combining the illumination condition, the imaging condition, and the edge extraction condition changed in a plurality of ways, and an optimum condition is determined (step SL3). However, since it takes a lot of time to detect an accurate imaging height when the search range is wide, a search condition of the imaging height may be determined on the basis of the height profile of the measurement element and around the measurement element acquired by the coarse detection in step SL2. Specifically, a search range of a limited imaging height is determined on the basis of the height profile. A height pitch when the imaging height is searched for may be set in advance or may be determined on the basis of the height profile. In addition, a type of an epi-illumination to be searched for and a height position of the epi-illumination may be set in advance, or may be determined on the basis of the height profile. Further, the type of the edge extraction condition to be searched for may be set in advance or may be determined on the basis of the height profile.

In step SL3, the automatic adjustment section 117 performs the automatic exposure adjustment on the target measurement element at the height on the basis of the height profile acquired by the coarse detection in step SL2. The automatic adjustment section 117 determines an optimum condition on the basis of the result of the search as described above. By the automatic exposure adjustment, at least one of parameters regarding the brightness of the obtained workpiece image, such as the exposure time of the imaging section 15, the brightness of the epi-illumination, and the gain for the workpiece image data, is determined. The automatic adjustment section 117 sequentially applies a set of candidates from a plurality of imaging height candidates of the imaging height and a plurality of illumination candidates of the type of the illumination and the illumination height, and sequentially acquires workpiece images under different conditions on the basis of the parameters determined by the automatic exposure adjustment. The automatic adjustment section 117 extracts edge candidates by executing the edge extraction processing on the workpiece images sequentially acquired under different conditions. The automatic adjustment section 117 evaluates whether or not an optimal edge is extracted by applying a predetermined evaluation criterion to the extracted edge candidate. The evaluation criterion includes straightness (roundness) of the extracted edge, a variation of each point constituting the edge, edge strength, closeness to the dimension, and a weighted combination thereof. The automatic adjustment section 117 determines an optimum condition on the basis of the evaluation result of the edge candidate, and the imaging height, the illumination condition, and the edge extraction condition when the edge candidate is acquired. The edge position of the edge candidate extracted by the edge extraction processing can be optimized, for example, in the vicinity of an edge of a step or in the vicinity of an area center line, and edge robustness can be achieved from the edge strength, the edge position variation, and the like. With respect to the edge position optimization, it is possible to switch which edge position is adopted in accordance with a situation. For example, in the case of a measurement element manually created by the user viewing the workpiece image, a measurement element in the vicinity of the area center line is adopted, and in the case of a measurement element automatically generated from the DXF data or the drawing, since there is a high possibility that the position of the area center line is shifted, a measurement element in the vicinity of the end of the step is adopted.

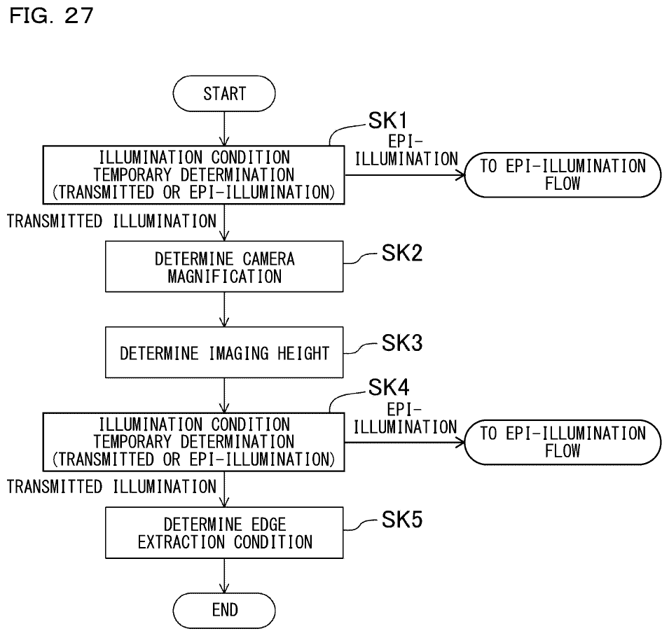

FIG. 27 illustrates an example of an adjustment order of the plurality of measurement conditions. In step SK1, the automatic adjustment section 117 temporarily determines the illumination condition to be either the transmitted illumination or the epi-illumination. In a case where the illumination is determined to be the transmitted illumination, the processing proceeds to step SK2. On the other hand, in a case where the illumination is determined to be the epi-illumination, the processing proceeds to an epi-illumination flowchart to be described later.

In step SK2, the automatic adjustment section 117 determines a camera magnification. In step SK3, the automatic adjustment section 117 determines the height of the stage 12, that is, the imaging height of the workpiece W. In step SK4, the automatic adjustment section 117 determines the illumination condition to be either the transmitted illumination or the epi-illumination. In a case where the illumination is determined to be the transmitted illumination, the processing proceeds to step SK5. On the other hand, in a case where the illumination is determined to be the epi-illumination, the processing proceeds to an epi-illumination flowchart to be described later. In step SK5, the edge extraction condition is determined.

In the adjustment result obtained by the automatic adjustment processing illustrated in the flowcharts of FIGS. 26 and 27, not only one optimum candidate but also several candidates having a high possibility of being correct may be selected. In a case where a plurality of candidates is selected, for example, the candidates can be presented to the user by being displayed in the adjustment result display region 323 or the like of the user interface screen 320 illustrated in FIG. 25.

The automatic adjustment processing illustrated in the flowcharts of FIGS. 26 and 27 is executed on one measurement element, and when the automatic adjustment processing is executed on a plurality of measurement elements, an adjustment time may be prolonged. Therefore, in order to reduce a time when the automatic adjustment processing is executed on the plurality of measurement elements, points that can be processed at the same time may be shared. For example, determination is made by using the same image for measurement elements that fall within the same visual field in imaging at the time of the transmitted illumination for epi-illumination determination in steps SK1 and SK4 of FIG. 27. In addition, in processing of acquiring a transmitted illumination image stack and calculating a best focus height, measurement elements that fall within the same visual field are processed by using the same transmitted illumination image stack. In addition, in order to maximize the time reduction by optimization processing thereof, a range and a position of the imaging visual field are calculated such that as many measurement elements as possible are included in the same visual field, and imaging by the imaging section 15 is executed.

### (Causing Automatic Adjustment Processing to be in Background)

In order to reduce a waiting time during the execution of the automatic adjustment processing, it is also possible to cause the automatic adjustment processing to be in the background. For example, during the automatic adjustment processing, another user interface screen is displayed on the display section 101 or the like, and thus, various input operations, selection operations, and the like can be performed. As a result, a substantial waiting time can be reduced.

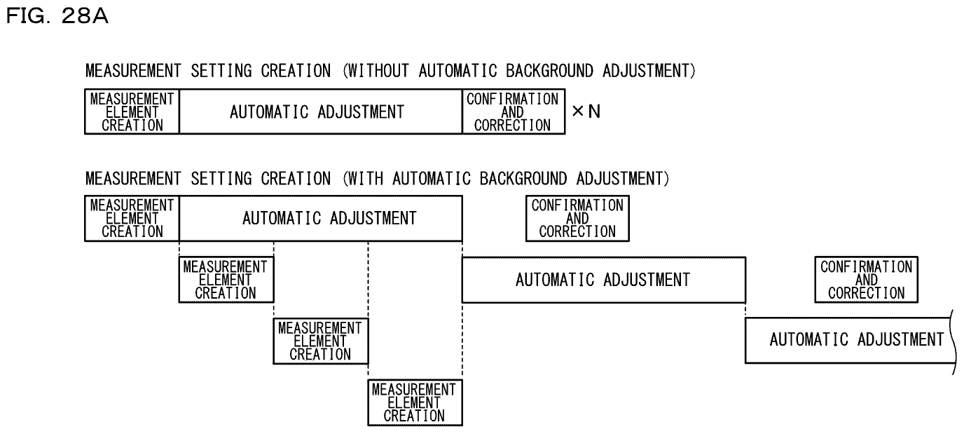

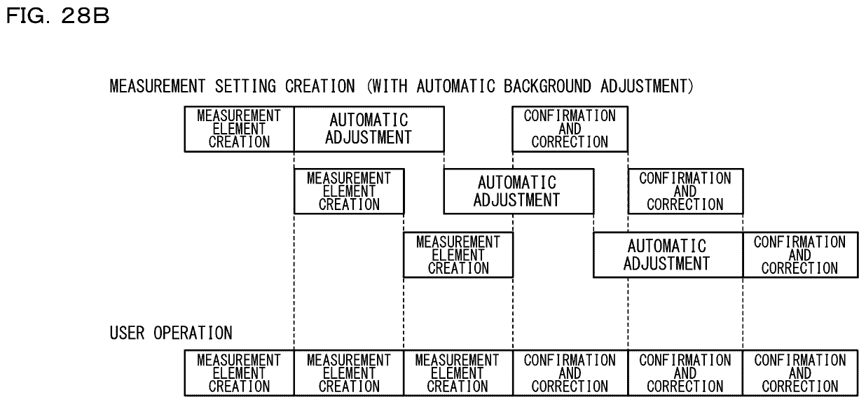

For example, as illustrated in FIG. 28A, in a case where the background automatic adjustment is not performed at the time of measurement setting creation, the automatic adjustment processing is executed on the created measurement element after the measurement element creation, and the user confirms and corrects the measurement element after the automatic adjustment processing is completed. This procedure is repeated by the number of measurement elements (N).

On the other hand, in a case where the background automatic adjustment is performed at the time of measurement setting creation, second measurement element creation, third measurement element creation, fourth measurement element creation, and the like can be performed while the automatic adjustment processing is executed on the first measurement element after the first measurement element creation. When the automatic adjustment processing for the first measurement element is ended, the user confirms and corrects the result. While the user confirms and corrects, the automatic adjustment processing is executed on the second measurement element.

FIG. 28B illustrates another example of the background automatic adjustment. As illustrated in this drawing, depending on a relationship between a length of a time of the measurement element creation and the confirmation and correction by the user operation and a time of the automatic adjustment processing, the user can perform the operation without being conscious of the waiting time of the automatic adjustment processing.

### (During Operation of Image Measurement Apparatus)

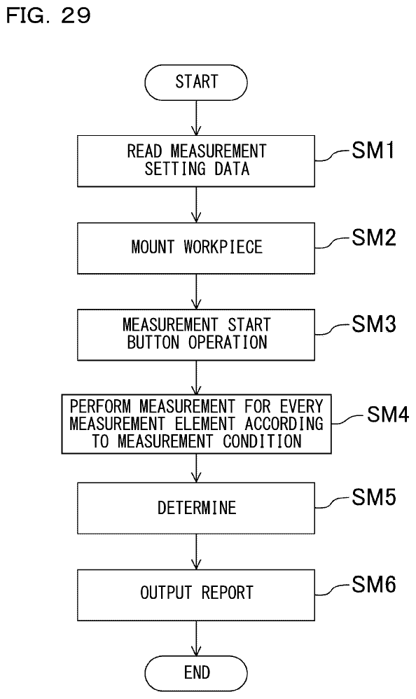

Next, an operation of the image measurement apparatus 1 will be described with reference to a flowchart illustrated in FIG. 29. In step SM1, the measurement section 110A reads the measurement setting data. The measurement setting data includes the measurement element set by the measurement setting section 113 and the measurement condition automatically adjusted by the automatic adjustment section 117, and thus includes the measurement position and the measurement item set for the workpiece representation included in the image generated by the imaging section 15.

In step SM2, the user places the workpiece W on the stage 12. In step SM3, the user operates the measurement start button included in the operation section 14. In step SM4, the measurement section 110A measures the workpiece according to the measurement setting data generated on the basis of the measurement position and the measurement element set by the measurement setting section 113 and the measurement condition automatically adjusted by the automatic adjustment section 117. For example, the measurement section 110A acquires the measurement item and the measurement element set by the measurement setting section 113 and the measurement condition automatically adjusted by the automatic adjustment section 117, extracts an edge from the workpiece image generated by the imaging section 15 on the basis of the acquired measurement item, measurement element, and measurement condition, and executes measurement of the measurement element by using the edge. That is, the measurement section 110A is a section that controls the measurement of the workpiece W on the basis of the measurement position or the measurement item and the measurement element reflected by the measurement setting section 113 and the measurement condition automatically adjusted by the automatic adjustment section 117, and is an example of a measurement control section. The measurement section 110A acquires a measurement result according to the measurement setting data.

The associating section 119 of the control unit 110 associates the measurement result with the workpiece representation visually associated with the workpiece shape included in the drawing data on the display screen generated by the display screen generation section 115. In addition, the associating section 119 associates the workpiece shape included in the drawing data taken in by the drawing intake section 111 with the measurement result for the workpiece representation included in the image generated by the imaging section 15. As a result, the measurement result acquired by the measurement section 110A can be displayed in a state of being associated with the measurement element. In addition, the associating section 119 can also associate the measurement result with the workpiece representation visually associated with the workpiece shape positioned at an imaging visual field center of the paper drawing.

When the measurement is ended for every measurement element, the processing proceeds to step SM5. In step SM5, the measurement section 110A compares the measurement result obtained in step SM4 with a determination threshold, and determines that “good” when the measurement result does not exceed the determination threshold, and determines that “poor” when the measurement result exceeds the determination threshold.

After the determination result is acquired in step SM5, the processing proceeds to step SM6. In step SM6, the measurement section 110A creates and outputs a report summarizing the measurement result acquired in step SM5 and the determination result acquired in step SM6. The report may be created in a predetermined format and may be output by data, or may be output by printing.

### (Setting Support Device for Image Measurement Apparatus)

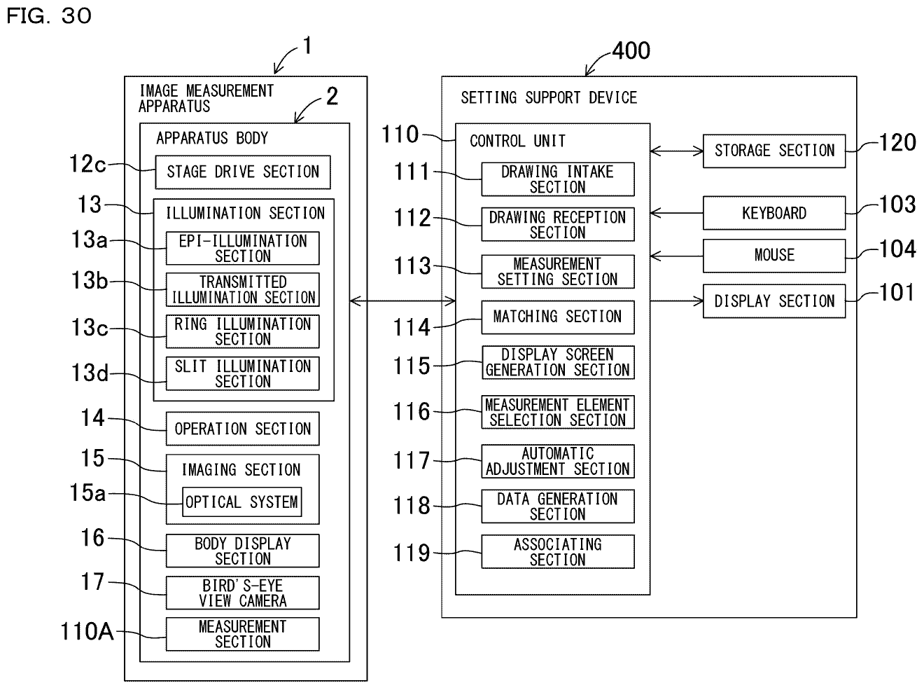

FIG. 30 illustrates a setting support device 400 for an image measurement apparatus that supports setting by the user of the image measurement apparatus 1, as another aspect of the embodiment according to the present invention. The image measurement apparatus 1 includes the apparatus body 2 of the above embodiment and the measurement section 110A. The measurement section 110A may be constituted by another arithmetic processing device or the like, or may be physically separated from the apparatus body 2.

The setting support device 400 for the image measurement apparatus includes the drawing intake section 111, the drawing reception section 112, the measurement setting section 113, the matching section 114, the display screen generation section 115, the measurement element selection section 116, the automatic adjustment section 117, the data generation section 118, and the associating section 119 of the control unit 110, and also includes the storage section 120, the keyboard 103, the mouse 104, and the display section 101. The operation of each section is as described above.

Accordingly, the user performs the above-described operation, and thus, the setting support device 400 for the image measurement apparatus executes setting processing such that the measurement section 110A extracts the edge from the workpiece image generated by the imaging section 15 on the basis of the measurement position or the measurement item reflected by the measurement setting section 113, the measurement element, and the measurement condition automatically adjusted by the automatic adjustment section 117 and measures the measurement element by using the extracted edge.

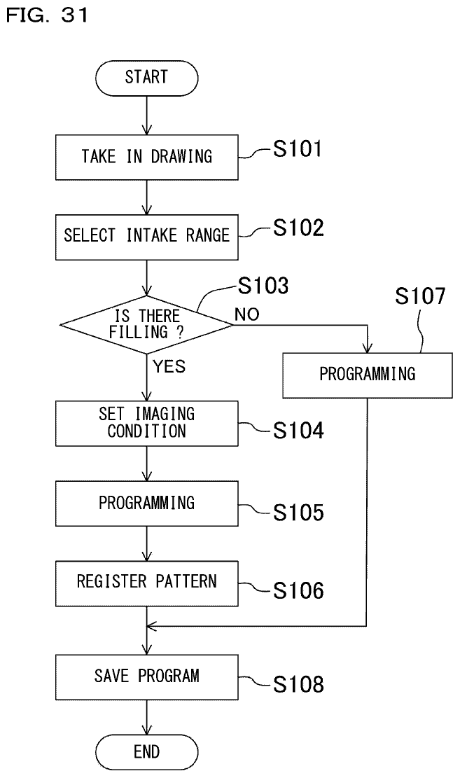

FIG. 31 is a flowchart illustrating an example of offline programming processing. Offline means creating measurement setting without using the actual workpiece W. Offline, since the actual workpiece W is not used when the measurement setting is created, the apparatus body 2 is also not used. Note that, the measurement setting can be created online, and in this case, the measurement setting is created by using the actual workpiece W. Since the actual workpiece W is used when the measurement setting is created online, the apparatus body 2 is also used.

On line, the measurement setting section 113 can set, as the measurement element, at least one of the plurality of measurement positions or one or more measurement items for the workpiece W displayed on the display section 101. The measurement setting section 113 sets, as the measurement element, at least one of the plurality of measurement positions or one or more measurement items by reflecting setting information set for the workpiece W displayed on the display section 101 in the workpiece representation included in the image generated by the imaging section 15.

On the other hand, offline, the measurement setting section 113 executes saving processing for saving setting information in which at least one of the plurality of measurement positions or one or more measurement items for the workpiece representation is set as the measurement element. The saving place of the setting information is not particularly limited, but may be, for example, the storage section 120 or the like. The measurement setting section 113 reads the setting information saved by the saving processing, and reflects the read setting information in the workpiece representation included in the image generated by the imaging section 15. As a result, at least one of the plurality of measurement positions or one or more measurement items can be set as the measurement element for the workpiece representation.

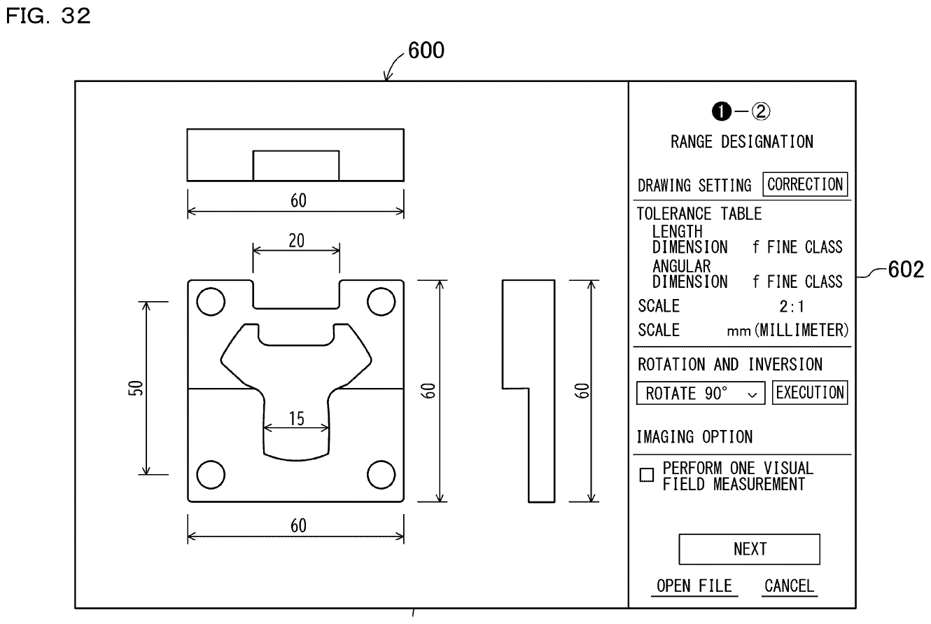

In step S101 after the start, the drawing reception section 112 takes in the drawing data including the workpiece shape and the dimensional information. FIG. 32 illustrates a user interface screen 600 that displays the image on the basis of the drawing data taken in by the drawing reception section 112. The user interface screen 600 is generated by the display screen generation section 115 and displayed on the display section 101.

A first display region 601 for displaying the image on the basis of the drawing data taken in by the drawing reception section 112 and a second display region 602 for displaying, for example, an operation procedure or the like are provided on the user interface screen 600. Since the drawing data taken in by the drawing reception section 112 includes the workpiece shape and the dimensional information, the workpiece shape, the dimension line, and the value are displayed in the first display region 601.

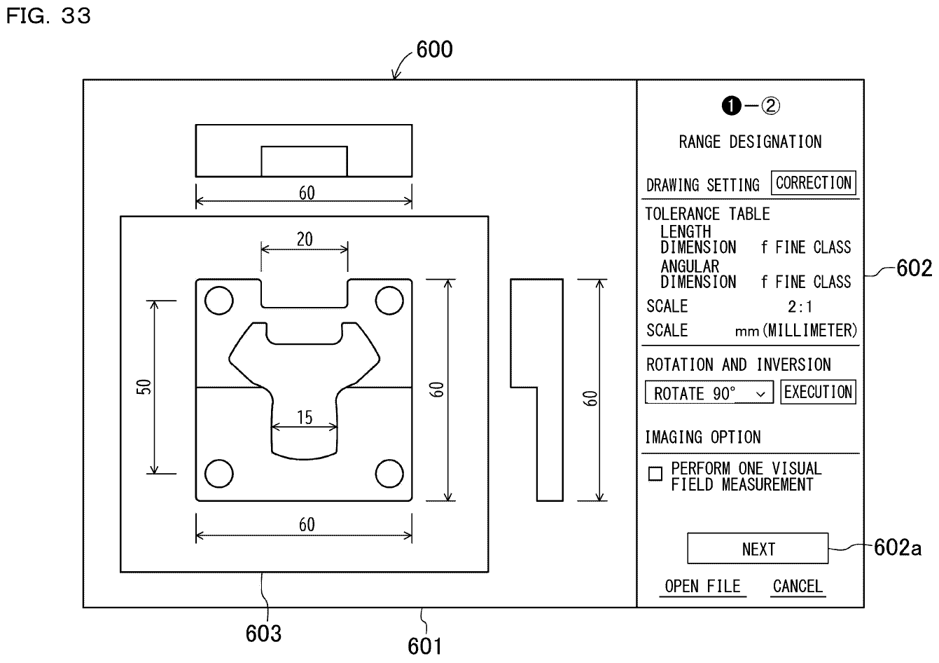

In step S102 illustrated in FIG. 31, the user selects the intake range from the drawing data taken in in step S101. Specifically, while viewing the drawing data on the user interface screen 600 displayed on the display section 101, the user operates the mouse 104 or the like to designate the range such that a region requiring dimension measurement is included in the intake range. In FIG. 33, the designated range is indicated by a rectangular frame line 603. The drawing intake section 111 takes in the drawing data within the range for which the intake instruction is given by the user. Examples of the range designation operation include a drag operation and the like. Step S102 can be omitted, and in the case of omission, the entire drawing data is taken in.

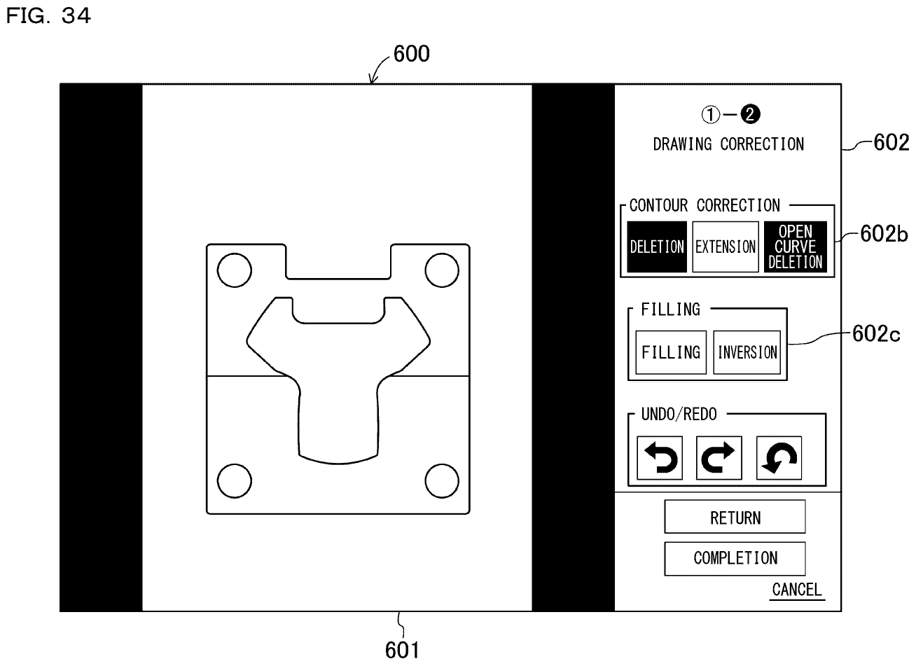

As illustrated in FIG. 33, a “next” button 602a is provided in the second display region 602. When the user operates the “next” button 602a after the intake range is selected, the intake range is confirmed. After the intake range is confirmed, as illustrated in FIG. 34, the drawing data within the range for which the intake instruction is given is displayed in the first display region 601. In addition, in the second display region 602, a display form in which an operation of correcting the drawing can be received is displayed, and for example, a contour correction tool 602b, a flood filling tool 602c, and the like are displayed.

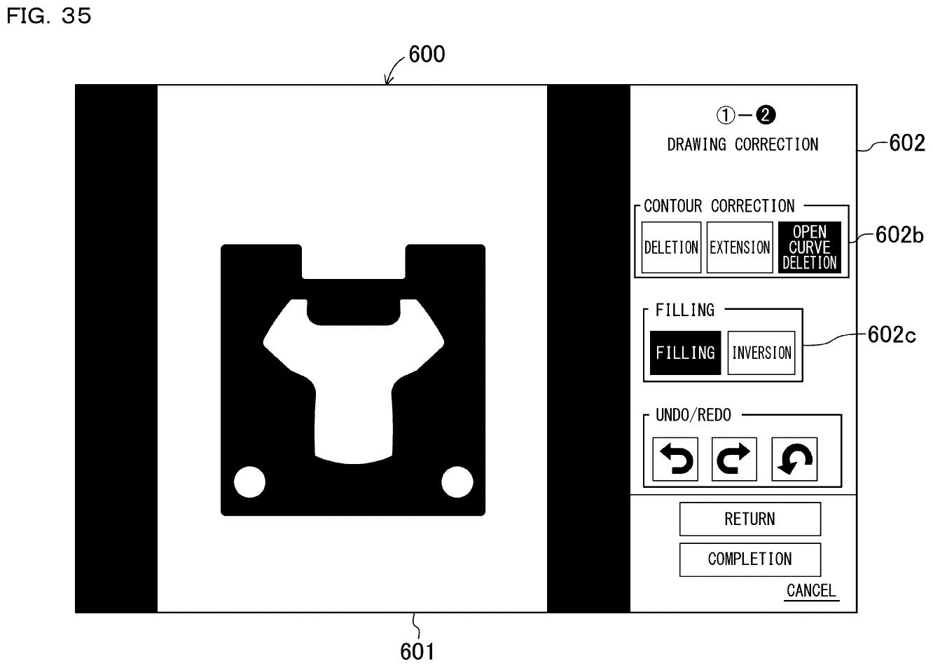

FIG. 35 illustrates a state where a desired place is filled by using the flood filling tool 602c. Specifically, the user performs an operation of deleting an unnecessary portion of the drawing data and filling a shadow portion. In a case where the unnecessary portion is deleted, the user can delete the unnecessary portion by performing a deletion operation and selecting the unnecessary portion on the drawing data displayed on the screen. In a case where a shadow portion is to be filled, the shadow portion can be filled by performing a filling operation and selecting a portion to be filled on the drawing data displayed on the screen.

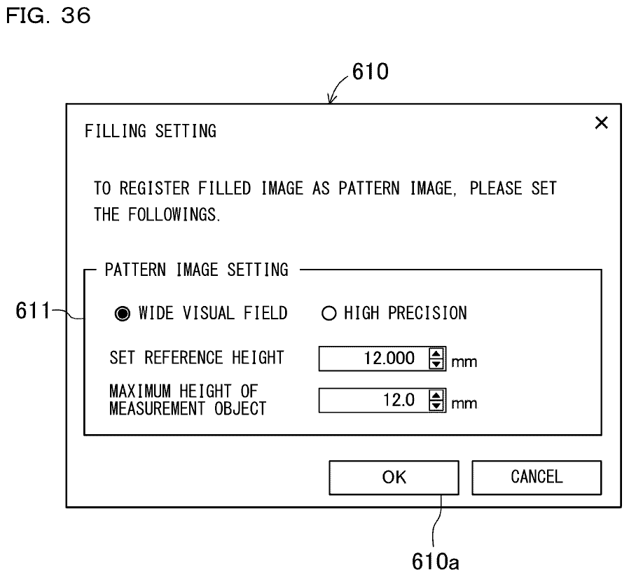

When flood filling processing is executed by using the flood filling tool 602c, YES is determined in step S103 in FIG. 31, and the processing proceeds to step S104. In step S104, imaging condition setting using a setting window 610 for the flood filling processing illustrated in FIG. 36 is performed. In a case where it is detected that the flood filling tool 602c is operated, the setting window 610 for the flood filling processing is generated by the display screen generation section 115 and displayed on the display section 101.

A pattern image setting region 611 is provided in the setting window 610 for the flood filling processing. In the pattern image setting region 611, it is possible to set which one of a wide view image and a high precision image is used as a pattern image, and it is also possible to set a reference height and a maximum height of the measurement object (workpiece W). When an “OK” button 610a provided in the setting window 610 for the flood filling processing is operated, the setting is reflected.

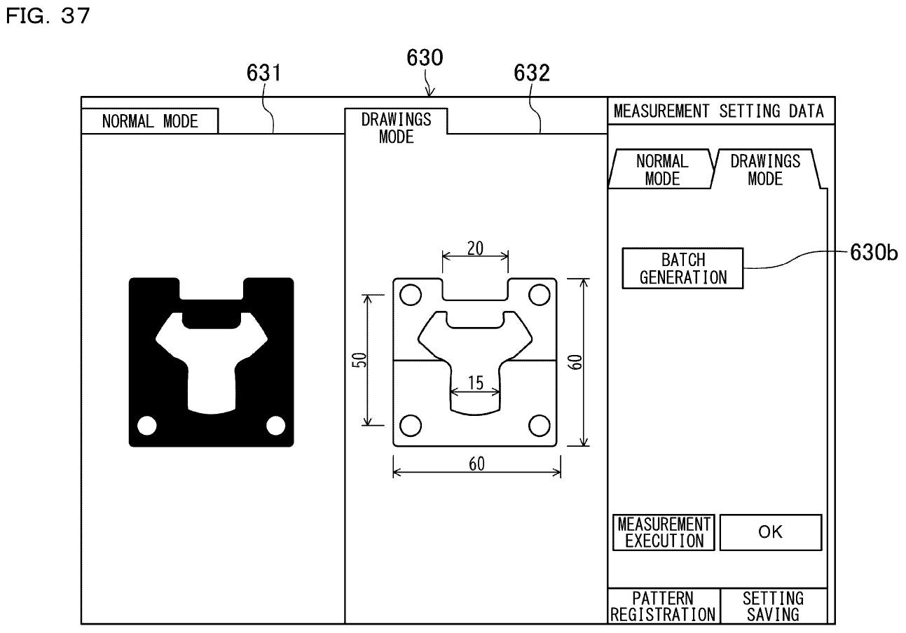

When the “OK” button 610a of the setting window 610 for the flood filling processing is operated, the processing proceeds to step S105 in FIG. 31. In step S105, a program is created. In step S105, the display screen generation section 115 generates a user interface screen 630 capable of performing two-screen display illustrated in FIG. 37, and displays the user interface screen on the display section 101.

A normal mode display region 631 and a drawing mode display region 632 are provided on the user interface screen 630 capable of performing two-screen display. In the normal mode display region 631, the workpiece shape is displayed. A normal mode can be used in a case where the dimension is directly measured for the workpiece W without using the drawing data. For example, the present invention can be used in a case where a dimension that is not included in the drawing data is measured. On the other hand, in the drawing mode display region 632, the drawing data within the range for which the intake instruction is given in step S102 is displayed. A drawing mode can be used in a case where the dimension in the drawing data is measured.

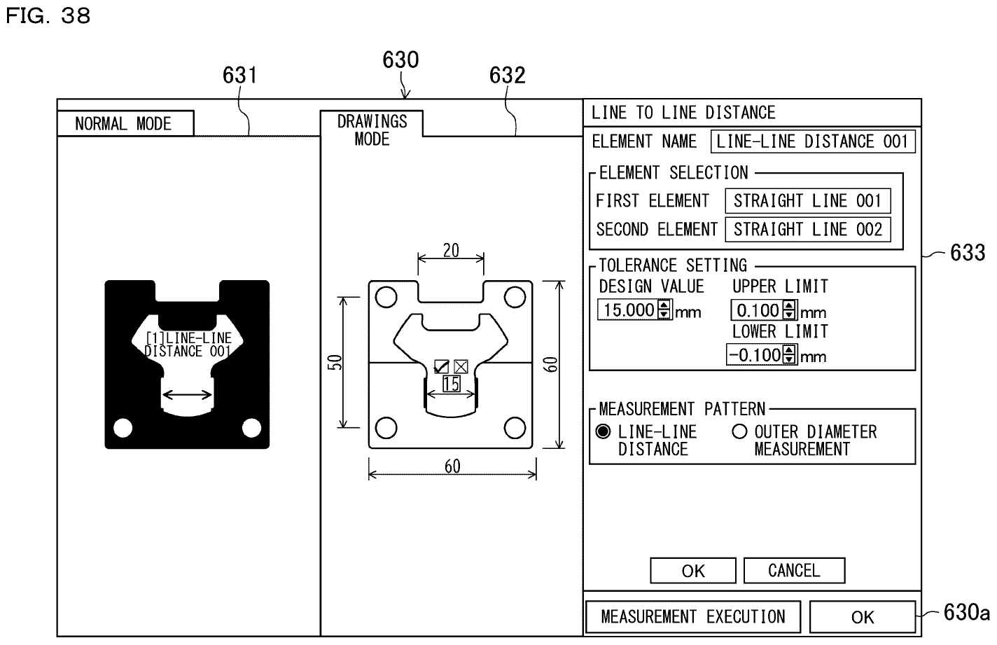

The user designates the measurement position or the measurement item on the drawing data displayed in the drawing mode display region 632. Specifically, as illustrated in FIG. 38, in a case where it is desired to measure a distance (dimension) between two straight lines (measurement elements), the dimension measurement point is selected on the drawing data displayed in the drawing mode display region 632 by using the mouse 104 or the like. When the dimension measurement point is selected, two straight lines corresponding to the dimension measurement point are specified, and the specified two straight lines and the dimension are displayed in an associated manner. The selection example of FIG. 38 is an example, and it is also possible to select another dimension measurement point included in the drawing data. In addition, a specifying section 110B may specify a correspondence relationship between the dimension and the line used for dimensioning. In the case of the CAD data, for example, it can be specified by using dimension of the CAD data and known identification information of the line used for dimensioning. In addition, in the case of the non-CAD data, it can be specified on the basis of, for example, a distance between the dimension read by the OCR or the like and the line used for dimensioning. In a case where the dimension is selected on the drawing data, the display screen generation section 115 can integrally display the selected dimension and the line used for dimensioning corresponding to the selected dimension on the basis of the correspondence relationship specified by the selected specifying section. Here, integrally displaying means displaying the dimension and the line used for dimensioning in association with each other, such as enlarging the dimension and the line used for dimensioning, displaying the dimension and the line in the same color, or displaying the dimension and the line surrounded by the object. In addition, in a case where the line used for dimensioning is selected on the drawing data, display screen generation section 115 may integrally display the selected line used for dimensioning and the corresponding dimension on the basis of the correspondence relationship specified by the selected specifying section. It is effective in that the user can grasp the dimension or the corresponding line used for dimensioning by selecting the line used for dimensioning or the dimension.

In addition, in a case where the drawing intake section 111 takes in the non-CAD data, the specifying section 110B can specify a correspondence relationship between the measurement element and the dimensional information from the measurement element of the workpiece shape included in the drawing data read by the OCR or the like and the dimensional information including the dimension similarly read and the line used for dimensioning. For example, the correspondence relationship may be specified on the basis of a positional relationship between the dimensional information including the dimension and the line used for the dimensioning and the measurement element of the workpiece shape on the drawing data. In a case where there is a plurality of candidates for the measurement element specified on the basis of the positional relationship, a candidate having a shortest distance between the measurement element and the line used for dimensioning may be displayed, or a plurality of candidates may be presented on the user interface screen 630, and one measurement element may be specified on the basis of the selection of the user. In a case where a measurement element having a shortest distance between the measurement element and the line used for dimensioning is displayed as the candidate, the selection operation by the user can be omitted since the specification is automatically performed, and in a case where the selection by the user is accepted, it is effective in that the measurement element not intended by the user can be prevented from being selected.

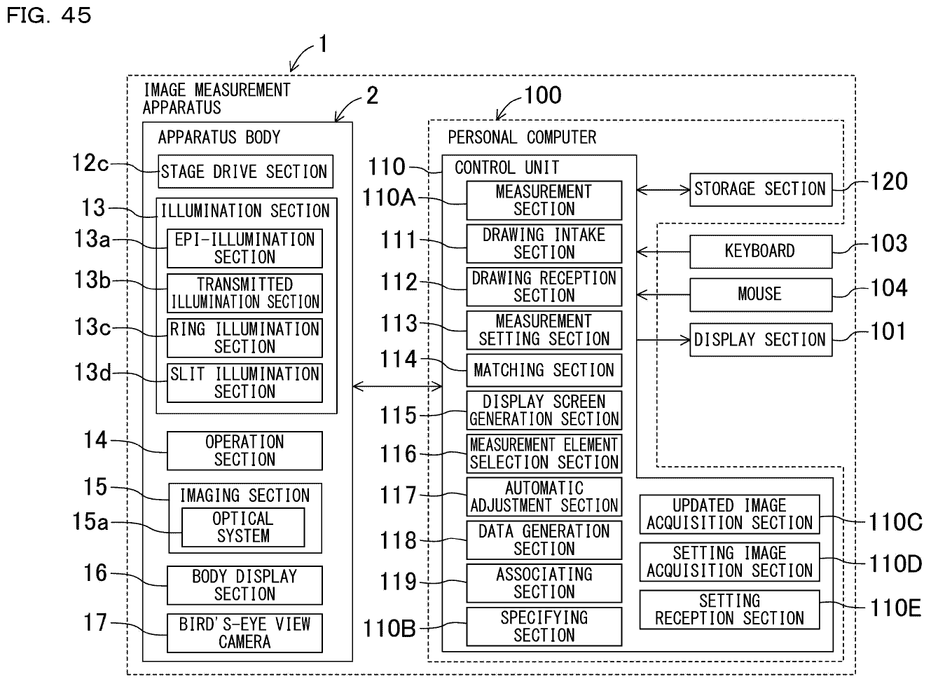

As in the configuration example illustrated in FIG. 45, the control unit 110 includes the specifying section 110B that specifies the correspondence relationship between the measurement element in the workpiece shape and the dimensional information. The specifying section 110B acquires the dimensional information included in the drawing data. When the measurement element in the workpiece shape is specified by the user, the specifying section 110B can acquire the dimensional information corresponding to the measurement element.

As illustrated in FIG. 38, two straight lines and dimensions as the measurement elements are also displayed in the normal mode display region 631. In addition to selecting the dimensions, for example, an operation of coupling two straight lines as one straight line by a drag operation or the like can also be performed. The illustrated straight line is an example of an element type, and the element type includes not only a straight line but also a circle, an arc, and the like, for example. An element type to be measured can be selected from these element types. When the measurement element is selected, a position (element position) of the selected measurement element is also specified.

In addition, it is also possible to set a plurality of measurement positions or measurement items. As described above, the display screen generation section 115 generates, as a screen illustrated in FIG. 38, a display screen that displays a figure corresponding to a candidate for the measurement element corresponding to an instruction and dimensional information on the drawing data on the basis of the reception of the selection operation of the figure or the dimensional information corresponding to the measurement element in the workpiece shape and the correspondence relationship specified by the specifying section 110B.

The user interface screen 630 is provided with a detailed display region 633 in which details of the element are displayed. In the detailed display region 633, an element name, a first element, a second element, and the like are displayed, and a tolerance setting (design value, upper limit, and lower limit) input field and the like are displayed. In a case where a tolerance can be read from the drawing data, the tolerance is reflected, and in a case where the tolerance cannot be read or when the tolerance is not described, the tolerance is automatically input on the basis of a tolerance table. When the user operates an “OK” button 630a provided on the user interface screen 630 capable of performing two-screen display, the setting of the measurement position or the measurement item is confirmed.

In addition to the operation of individually generating the measurement position or the measurement item, it is also possible to generate the measurement position or the measurement item in a batch manner. For example, when the user operates a “batch generation” button 630b provided on the user interface screen 630 capable of performing two-screen display illustrated in FIG. 37, all the measurement positions or measurement items included in the drawing data are generated in a batch manner.

As described above, since the image measurement apparatus 1 has a function capable of generating the measurement items and the measurement elements in a batch manner on the basis of a determined rule, it is not necessary for the user to generate the plurality of measurement items and measurement elements, and a burden can be reduced. On the other hand, when an unnecessary measurement item is generated or an undesired measurement element is generated, there is a case where the measurement program intended by the user is not generated.

On the other hand, in the present embodiment, a setting reception section 110E illustrated in FIG. 45 is provided. The setting reception section 110E receives setting information including shape information regarding the shape of the workpiece W, a measurement element for the shape of the workpiece W, and a measurement item regarding the measurement element. In a case where there is a plurality of measurement elements, the setting reception section 110E can receive setting information including the plurality of measurement elements and measurement items regarding the measurement elements. As a result, since only the measurement element for which the user desires measurement can be received, it is possible to create a measurement program intended by the user without generating the unnecessary measurement item or generating the undesired measurement element.

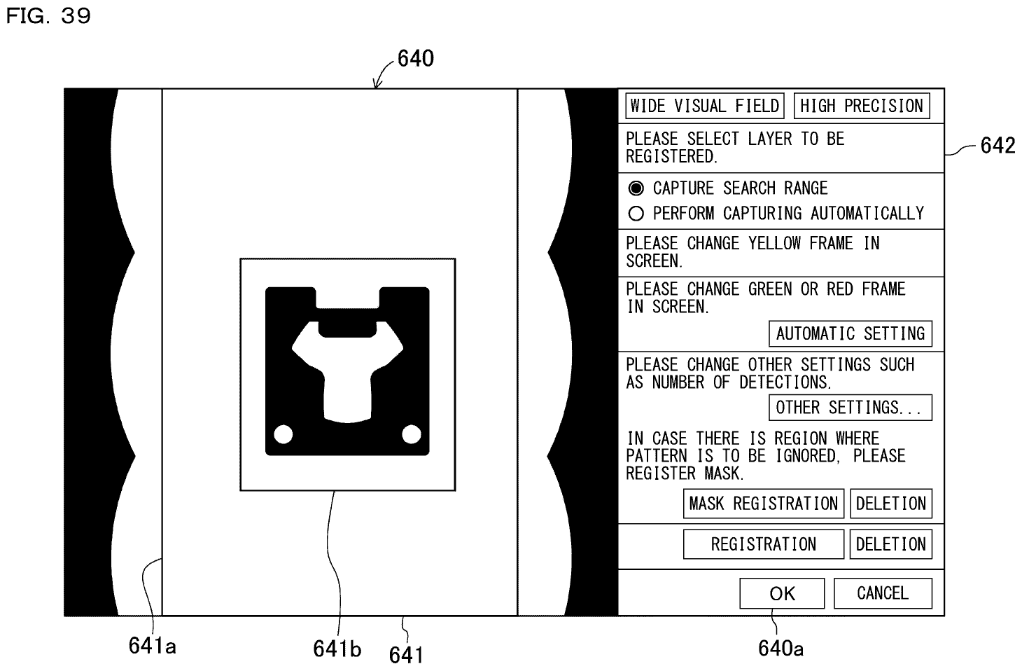

In step S106 illustrated in FIG. 31, pattern image registration processing of registering a pattern image for pattern search is executed. In the pattern registration processing, the display screen generation section 115 generates a pattern registration user interface screen 640 illustrated in FIG. 39 and displays the pattern registration user interface screen on the display section 101.

An image display region 641 and a registration setting region 642 are provided on the pattern registration user interface screen 640. In the image display region 641, an image captured by the imaging section 15 is displayed, and a first frame 641a indicating a search range that is a range in which pattern search is executed and a second frame 641b for designating a pattern region including a characteristic portion are displayed. The second frame 641b can be arranged in any size at any position on the image by the user operating the mouse 104 or the like.

A selection field for selecting whether to set a wide view image or a high accuracy image, a selection field for selecting a layer to be registered, a selection field for selecting whether to capture a search range as a capturing method or automatically, a mask registration field for masking a pattern to be ignored, and the like are provided in the registration setting region 642. When an “OK” button 640a provided on the pattern registration user interface screen 640 is operated, the setting of the pattern search is reflected. The order of step S106 and step S105 illustrated in FIG. 31 may be inversed.

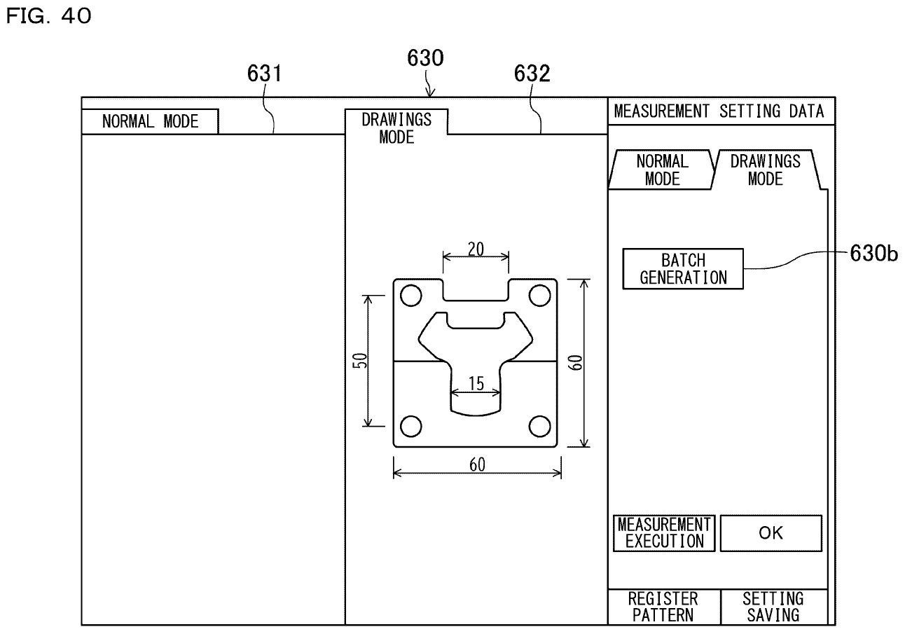

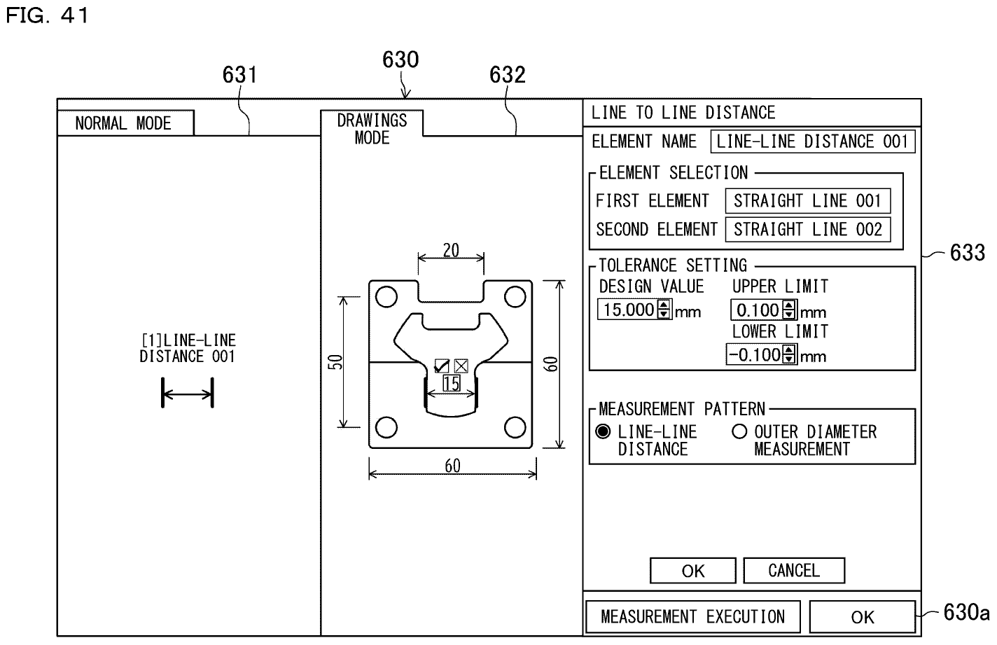

On the other hand, in a case where NO is determined in step S103 illustrated in FIG. 31 and there is no filling, the processing proceeds to step S107. In step S107, a program is created similarly to step S105. FIG. 40 illustrates the user interface screen 630 capable of performing two-screen display in a case where there is no filling. FIG. 41 illustrates a case where the dimension is selected on the user interface screen 630 in a case where there is no filling.

In step S108 illustrated in FIG. 31, the program created in step S105 and the program created in step S107 are saved in, for example, the storage section 120 or the like.

As described above, the program can be created offline. The program created offline can be read into the image measurement apparatus 1 online and adjusted. Hereinafter, processing of reading the program created offline into the image measurement apparatus 1 online and adjusting the program will be described.

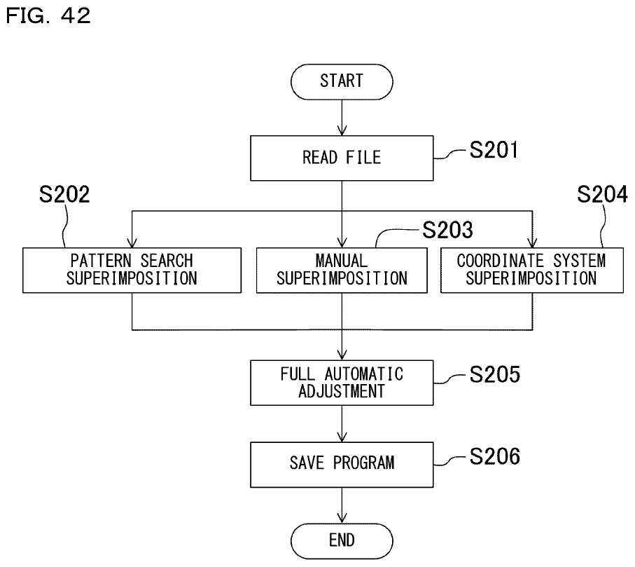

FIG. 42 is a flowchart illustrating an example of processing in a case where the program created offline is read into the image measurement apparatus 1 online. In step S201 after the start, a file of the program created offline is read. For example, a button for starting reading such as an edit button is displayed on the display section 101, and when the user operates the button for starting reading, a file of a desired program is read.

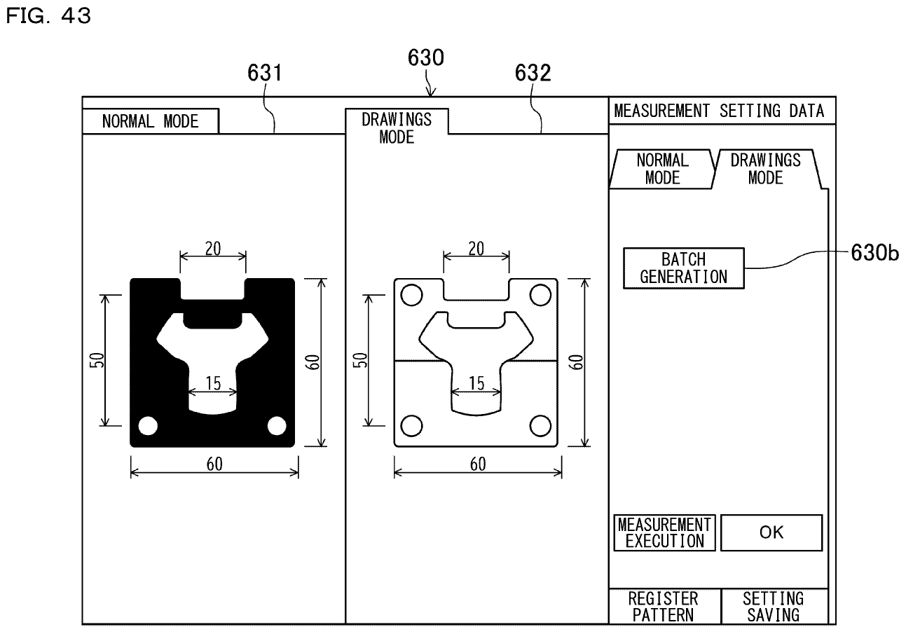

In a case where there is filling and there is registration of a pattern image for pattern search, as illustrated in FIG. 43, a pattern image and drawing data are displayed on the two-screen displayable user interface screen 630.

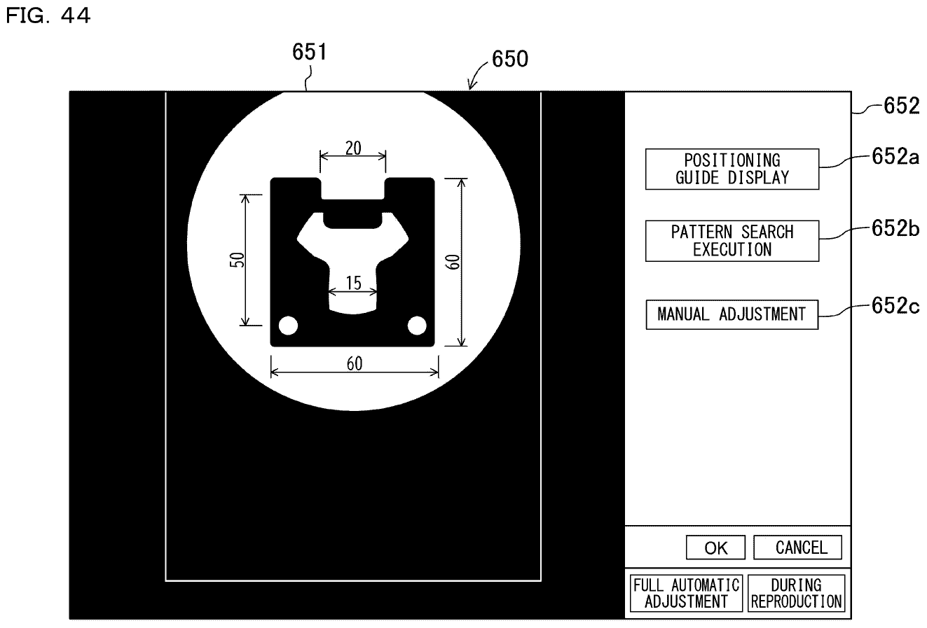

FIG. 44 illustrates a screen 650 on which the created program is superimposed on the workpiece W mounted on the stage, and is generated by the display screen generation section 115 and displayed on the display section 101. A superimposition display region 651 and an operation region 652 are provided on the superimposition screen 650. A positioning guide display button 652a for displaying a guide for guiding the workpiece W to a predetermined mounting place, a pattern search execution button 652b, and a manual adjustment button 652c are provided in the operation region 652. The pattern search is executed by operating the pattern search execution button 652b. In the pattern search, in a case where drawing filling is performed, pattern matching of the filled portion is executed, and in a case where there is no filling, pattern matching for best fitting the contour of the drawing and the contour of the workpiece W is executed.

When the pattern search is successful, the drawing data coincides with the workpiece representation. This processing is pattern search superimposition processing in step S202. This processing can be executed by the measurement setting section 113, and thus, the measurement position or the measurement item associated with the workpiece shape included in the drawing data can be reflected as the measurement position or the measurement item for the workpiece representation. More specifically, in a case where there is a plurality of candidates for the measurement element, the measurement setting section 113 displays the plurality of candidates for the measurement element on the screen. The measurement setting section 113 can receive the measurement element selected by the user from among the plurality of candidates displayed on the screen. The measurement setting section 113 reflects the element type, the element position, and the measurement item corresponding to the measurement element selected by the user in the measurement setting.

After the pattern search superimposition processing in step S202, the processing proceeds to step S205, and the automatic adjustment section 117 executes automatic adjustment for automatically adjusting the plurality of measurement conditions, for example, the illumination condition of the illumination section 13, the imaging condition of the imaging section 15, the edge extraction condition in the edge extraction processing executed by the measurement section 110A, and the like. Here, the measurement conditions are automatically adjusted for every measurement element. After the automatic adjustment by the automatic adjustment section 117, the measurement program after the automatic adjustment is saved in step S206.

In a case where the positioning by the pattern search in step S202 cannot be performed, the processing proceeds to step S203, and manual superimposition processing can be executed. In the manual superimposition processing, the user manually adjusts the position such that the dimension and the dimension line coincide with the workpiece representation. This position adjustment can be performed by the user operating the operation section 14. After the manual superimposition processing by the user, the processing proceeds to step S205, and the automatic adjustment section 117 executes automatic adjustment for automatically adjusting the plurality of measurement conditions. After the automatic adjustment, in step S206, the program after the automatic adjustment is saved.

In a case where the positioning by the pattern search in step S202 cannot be performed, the processing proceeds to step S204, and coordinate system superimposition processing may be executed. That is, in a case where the drawing data and the workpiece representation are shifted, the user sets the reference coordinate system. The reference coordinate system is set, and thus, it is possible to correct the position of the measurement point on the basis of the reference coordinate system. As a result, it is possible to quickly correct the position of the measurement point and measure the measurement point when the movement of the workpiece Wis slight. In addition, the coordinate system superimposition processing and the pattern search may be combined. The coordinate system superimposition processing and the pattern search are combined, and thus, more stable position correction can be performed.

When the reference coordinate is set, for example, two straight lines may be designated on the drawing data side to set the reference coordinate, or a straight line and a point may be designated to set reference coordinates. In addition, the coordinate system can be similarly set on the workpiece representation side. Then, an element for the coordinate system is designated on the workpiece representation side.

After the setting of the reference coordinates, a coordinate system of the drawing data and a coordinate system of the workpiece representation are superimposed. Specifically, the user operates the operation section 14 or the like to designate the same place as the element designated on the workpiece representation side on the drawing data. The superimposition is executed after being designated by the user, and thus, the processing of step S204 is completed. Thereafter, the processing proceeds to step S205, and the automatic adjustment section 117 executes automatic adjustment for automatically adjusting the plurality of measurement conditions. After the automatic adjustment, in step S206, the program after the automatic adjustment is saved.

In an updated image acquisition section 110C illustrated in FIG. 45, the imaging section 15 sequentially captures the workpiece W, and sequentially acquires, as an updated image, an image including the sequentially generated workpiece representations. The plurality of updated images have different measurement conditions.

In addition, a setting image acquisition section 110D acquires, as a setting image, an image regarding the shape of the workpiece W. In this case, the measurement setting section 113 can read the setting image acquired by the setting image acquisition section 110D. The measurement setting section 113 sets a plurality of measurement elements for the shape of the workpiece W and measurement items regarding the measurement elements on the basis of the setting image acquired by the setting image acquisition section 110D.

Inspection information of the workpiece W includes the measurement element. That is, there is the workpiece W in which at least one of the plurality of measurement positions or one or more measurement items is included in the inspection information as the measurement element. In this case, the setting information is set for the workpiece including at least one of the plurality of measurement positions or one or more measurement items as the measurement element in the inspection information. The measurement setting section 113 reflects the setting information set for the workpiece including, as the measurement element, at least one of the plurality of measurement positions or one or more measurement items in the inspection information on the workpiece representation included in the image generated by the imaging section 15. As a result, the measurement setting section 113 can set, as the measurement element, at least one of the plurality of measurement positions or one or more measurement items for the workpiece representation.

In a case where the imaging section 15 generates a plurality of images, a combined image obtained by combining the plurality of images can be generated. In this case, in the setting information, at least one of the plurality of measurement positions or one or more measurement items for the workpiece representation included in the combined image obtained by combining the images generated by the imaging section 15 is set as the measurement element. The measurement setting section 113 reflects the setting information in which at least one of the plurality of measurement positions or one or more measurement items for the workpiece representation included in the combined image obtained by combining the images generated by the imaging section 15 is set as the measurement element in the workpiece representation included in the image generated by the imaging section 15. As a result, the measurement setting section 113 can set, as the measurement element, at least one of the plurality of measurement positions or one or more measurement items for the workpiece representation. The combined image can be generated by the control unit 110.

The automatic adjustment section 117 acquires updated images having different measurement conditions sequentially acquired by the updated image acquisition section 110C. The automatic adjustment section 117 automatically adjusts a plurality of types of measurement conditions, for example, the illumination condition, the imaging condition, the edge extraction condition, and the like for every measurement element on the basis of the updated image and each measurement element set by the measurement setting section 113.

When a measurement instruction is received from the user, the measurement section 110A acquires the image including the workpiece representation generated by capturing the workpiece W by the imaging section 15. The measurement section 110A controls the measurement on the workpiece representation on the basis of the image including the acquired workpiece representation and the element type, the element position, and the measurement item reflected in the measurement setting by the measurement setting section 113. For example, the measurement section 110A can extract the edge from the image generated by the imaging section 15 on the basis of the measurement element set by the measurement setting section 113 and the measurement condition automatically adjusted by the automatic adjustment section 117, and specify the measurement element by using the edge. Then, the measurement of the measurement item of the setting information is executed on the basis of the specified measurement element.

Note that, in the setting support device 400 for the image measurement apparatus, the setting processing can be executed such that the measurement section 110A controls the measurement of the workpiece W on the basis of the image including the workpiece representation and the element type, the element position, and the measurement item reflected in the measurement setting by the measurement setting section 113.

The above-described embodiment is merely an example in all respects, and should not be construed in a limiting manner. Further, all modifications and changes falling within the equivalent scope of the claims are within the scope of the invention.

### INDUSTRIAL APPLICABILITY

As described above, the present invention can be used in a case where the dimension of each part of the workpiece is measured.

### REFERENCE SIGNS LIST

1 image measurement apparatus
12 stage (mounting table)
12a translucent plate
13a epi-illumination section
13b transmitted illumination section
15 imaging section
101 display section
111 drawing intake section
112 drawing reception section
113 measurement setting section
114 matching section
115 display screen generation section
117 automatic adjustment section
118 data generation section
119 associating section
110A measurement section

1. An image measurement apparatus comprising:
a mounting table that includes a translucent plate having translucency and on which a workpiece is mounted on a first surface of the translucent plate;
a transmitted illumination section that is provided below the translucent plate and irradiates the workpiece mounted on the translucent plate with transmitted illumination light;
an epi-illumination section that is provided above the translucent plate and irradiates the workpiece mounted on the translucent plate with epi-illumination light;
an imaging section that is provided above the mounting table and captures the workpiece mounted on the mounting table to generate an image including a workpiece representation;
a drawing reception section that receives drawing data including a workpiece shape and dimensional information;
a matching section that matches the workpiece shape included in the drawing data received by the drawing reception section with the workpiece representation included in the image generated by the imaging section;
a specifying section that specifies a correspondence relationship between a measurement element in the workpiece shape and the dimensional information;
a display screen generation section that generates a display screen that displays, based on reception of a selection operation of a figure corresponding to the measurement element in the workpiece shape or the dimensional information and the correspondence relationship specified by the specifying section, figures corresponding to candidates for the measurement element corresponding to the reception and dimensional information on the drawing data;
a measurement setting section that reflects an element type, an element position, and a measurement item corresponding to a measurement element selected from the candidates in measurement setting; and
a measurement control section that controls measurement on the workpiece representation based on an image including a workpiece representation generated by imaging the workpiece by the imaging section upon reception of a measurement instruction, and the element type, the element position, and the measurement item reflected in the measurement settings by the measurement setting section.

2. The image measurement apparatus according to claim 1,
wherein the display screen generation section
generates a workpiece representation display region for displaying the workpiece representation and a drawing data display region for displaying the drawing data, and
displays, based on reception of a selection operation of a figure corresponding to the measurement element in the workpiece shape on the drawing data display region or the dimensional information and the correspondence relationship specified by the specifying section, figures corresponding to candidates for a measurement element corresponding to the instruction and dimensional information in the other region, and
the measurement setting section reflects an element type, an element position, and a measurement item corresponding to a measurement element selected from the candidates on the workpiece representation matched with the workpiece shape included in the drawing data by the matching section.

3. An image measurement apparatus that executes measurement on a workpiece representation generated by receiving a measurement instruction to capture the workpiece based on an image including the workpiece representation and a preset element type, element position, and measurement item, the image measurement apparatus comprising:
a drawing reception section that receives drawing data including a workpiece shape and dimensional information;
a specifying section that specifies a correspondence relationship between a measurement element in the workpiece shape and the dimensional information;
a display screen generation section that generates a display screen that displays, based on reception of a selection operation of a figure corresponding to the measurement element in the workpiece shape or the dimensional information and the correspondence relationship specified by the specifying section, figures corresponding to candidates for the measurement element corresponding to the reception and dimensional information on the drawing data; and
a measurement setting section that reflects an element type, an element position, and a measurement item corresponding to the measurement element selected from the candidates in measurement setting.

4. The image measurement apparatus according to claim 3, further comprising:
a transmitted illumination section that is provided below the translucent plate and irradiates a workpiece mounted on the translucent plate with transmitted illumination light;
an epi-illumination section that is provided above the translucent plate and irradiates the workpiece mounted on the translucent plate with epi-illumination light;
an imaging section that is provided above the mounting table and captures the workpiece mounted on the mounting table to generate an image including a workpiece representation; and
a matching section that matches the workpiece shape included in the drawing data received by the drawing reception section and the workpiece representation included in the image generated by the imaging section,
wherein the display screen generation section displays a flood filling tool screen for filling a desired point on the drawing data,
the drawing reception section includes a drawing intake section that takes in drawing data in which flood filling processing is performed on a region designated on the flood filling tool screen,
the matching section matches the drawing data after the flood filling processing, which is taken in by the drawing weaving section, with the image including the workpiece representation obtained by the imaging section, by pattern matching, and
the measurement setting section reflects the element type, the element position, and the measurement item corresponding to the measurement element selected from the candidates on the drawing data after the flood filling processing taken in by the drawing intake section.

5. The image measurement apparatus according to claim 3, further comprising:
a transmitted illumination section that is provided below the translucent plate and irradiates the workpiece mounted on the translucent plate with transmitted illumination light;
an epi-illumination section that is provided above the translucent plate and irradiates the workpiece mounted on the translucent plate with epi-illumination light;
an imaging section that is provided above the mounting table and captures the workpiece mounted on the mounting table to generate an image including a workpiece representation; and
a matching section that matches the workpiece shape included in the drawing data received by the drawing reception section and the workpiece representation included in the image generated by the imaging section based on contours of the workpiece shape and the workpiece representation,
wherein the measurement setting section reflects the element type, the element position, and the measurement item corresponding to the measurement element selected from the candidates on the workpiece representation matched with the workpiece shape included in the drawing data.

6. The image measurement apparatus according to claim 1,
wherein the dimensional information includes a dimension and a line used for dimensioning,
the specifying section specifies a correspondence relationship between the dimension and the line used for dimensioning, and
the display control section integrally displays the dimension and the line used for dimensioning based on the correspondence relationship specified by the specifying section when the selection operation of the figure corresponding to the measurement element in the workpiece shape or the dimensional information is received.

7. The image measurement apparatus according to claim 1,
wherein the dimensional information includes a dimension and a line used for dimensioning, and
in a case where the drawing reception section receives CAD data, the specifying section identifies the dimension and the line used for dimensioning based on known identification information of the dimension and the line used for dimensioning, and specifies a correspondence relationship between the measurement element in the workpiece shape and the dimensional information based on a positional relationship between the line used for dimensioning and the measurement element.

8. The image measurement apparatus according to claim 1,
wherein the dimensional information includes a dimension and a line used for dimensioning, and
in a case where the drawing reception section receives non-CAD data, the specifying section reads the dimension and the line used for dimensioning, and specifies a correspondence relationship between the measurement element in the workpiece shape and the dimensional information based on a positional relationship between the line used for dimensioning and the measurement element.

9. A setting support device for an image measurement apparatus that supports setting of the image measurement apparatus, the image measurement apparatus including a mounting table that includes a translucent plate having translucency and on which a workpiece is mounted on a first surface of the translucent plate; a transmitted illumination section that is provided below the translucent plate and irradiates the workpiece mounted on the translucent plate with transmitted illumination light; an epi-illumination section that is provided above the translucent plate and irradiates the workpiece mounted on the translucent plate with epi-illumination light; an imaging section that is provided above the mounting table and captures the workpiece mounted on the mounting table to generate an image including a workpiece representation; and a measurement control section that controls measurement of the workpiece, the setting support device comprising:
a drawing reception section that receives drawing data including a workpiece shape and dimensional information; a matching section that matches the workpiece shape included in the drawing data received by the drawing reception section with the workpiece representation included in the image generated by the imaging section; a specifying section that specifies a correspondence relationship between a measurement element in the workpiece shape and the dimensional information; a display screen generation section that generates a display screen that displays, based on reception of a selection operation of a figure corresponding to the measurement element in the workpiece shape or the dimensional information and the correspondence relationship specified by the specifying section, figures corresponding to candidates for a measurement element corresponding to the reception and dimensional information on the drawing data; and a measurement setting section that reflects an element type, an element position, and a measurement item corresponding to a measurement element selected from the candidates in measurement setting,
wherein setting processing is executed such that the measurement control section controls measurement of the workpiece based on an image including a workpiece representation generated by capturing the workpiece by the imaging section upon reception of a measurement instruction, the element type, the element position, and the measurement item reflected in the measurement setting by the measurement setting section.

10. The setting support device for the image measurement apparatus according to claim 9,
wherein the dimensional information includes a dimension and a line used for dimensioning,
the specifying section specifies a correspondence relationship between the dimension and the line used for dimensioning, and
the display control section integrally displays the dimension and the line used for dimensioning based on the correspondence relationship specified by the specifying section when the selection operation of the figure corresponding to the measurement element in the workpiece shape or the dimensional information is received.

11. The setting support device for the image measurement apparatus according to claim 9,
wherein the display screen generation section
generates a workpiece representation display region for displaying the workpiece representation and a drawing data display region for displaying the drawing data, and
displays, based on reception of a selection operation of a figure corresponding to a measurement element in the workpiece shape on the drawing data display region or the dimensional information and the correspondence relationship specified by the specifying section, figures corresponding to candidates for a measurement element corresponding to the instruction and dimensional information in the other region, and
the measurement setting section reflects an element type, an element position, and a measurement item corresponding to a measurement element selected from the candidates on the workpiece representation matched with the workpiece shape included in the drawing data by the matching section.

12. The setting support device for the image measurement apparatus according to claim 9,
wherein the dimensional information includes a dimension and a line used for dimensioning, and
in a case where the drawing reception section receives CAD data, the specifying section identifies the dimension and the line used for dimensioning based on known identification information of the dimension and the line used for dimensioning, and specifies a correspondence relationship between the measurement element in the workpiece shape and the dimensional information based on a positional relationship between the line used for dimensioning and the measurement element.

13. The setting support device for the image measurement apparatus according to claim 9,
wherein the dimensional information includes a dimension and a line used for dimensioning, and
in a case where the drawing reception section receives non-CAD data, the specifying section reads the dimension and the line used for dimensioning, and specifies a correspondence relationship between the measurement element in the workpiece shape and the dimensional information based on a positional relationship between the line used for dimensioning and the measurement element.
